(19) United States
(12) Patent Application Publication
(10) Pub. No.: US 2025/0316462 A1
(43) Pub. Date: Oct. 9, 2025

(54) PLASMA PROCESSING APPARATUS AND SUBSTRATE ATTRACTION METHOD

(71) Applicant: Tokyo Electron Limited, Tokyo (JP)

(72) Inventors: Takehiro TANIKAWA, Miyagi (JP); Riichiro ENDO, Miyagi (JP); Kazuma KITA, Miyagi (JP)

(21) Appl. No.: 19/244,040

(22) Filed: Jun. 20, 2025

Related U.S. Application Data
(63) Continuation of application No. PCT/JP2023/046616, filed on Dec. 26, 2023.

(30) Foreign Application Priority Data
Dec. 28, 2022 (JP) 2022-212263
Sep. 15, 2023 (JP) 2023-150207

(51) Int. Cl. H01J 37/32

(52) U.S. Cl. CPC H01J 37/32715; H01J 37/32642; H01J 37/32091; H01J 2237/2007

(57) ABSTRACT

A plasma processing apparatus includes a plasma processing chamber; an electrostatic chuck disposed in the plasma processing chamber, the electrostatic chuck including a dielectric member including a substrate support surface and a ring support surface, and chuck electrodes disposed under the substrate support surface and the ring support surface in the dielectric member; and an alternating current voltage generator that applies AC voltages to the chuck electrodes disposed under the ring support surface, the AC voltages being phase-shifted relative to each other. The chuck electrodes disposed under the ring support surface include one chuck electrode and another chuck electrode that include arc portions. The arc portions of the one chuck electrode and the another chuck electrode are arranged alternately in a radial direction. The chuck electrodes disposed under the substrate support surface have a spiral shape and the chuck electrodes disposed under the ring support surface have a nested structure.

### CROSS-REFERENCE TO RELATED APPLICATIONS

This application is a continuation application of International Application No. PCT/JP2023/046616 filed on Dec. 26, 2023, and designating the U.S., which is based upon and claims priority to Japanese Patent Application No. 2022-212263, filed on Dec. 28, 2022, and Japanese Patent Application No. 2023-150207, filed on Sep. 15, 2023, the entire contents of which are incorporated herein by reference.

### BACKGROUND

### 1. Technical Field

The present disclosure relates to a plasma processing apparatus and a substrate attraction method.

### 2. Description of the Related Art

Patent Document 1 discloses an electrostatic attraction method for electrostatically attracting a focus ring provided on an electrostatic chuck.

Patent Document 2 discloses a substrate processing apparatus configured to electrostatically attract a substrate and an edge ring by applying an alternating current (AC) voltage to an electrode of an electrostatic chuck.

### RELATED ART DOCUMENT

### Patent Document

Patent Document 1: Japanese Laid-Open Patent Application Publication No. 2016-122740
Patent Document 2: Japanese Laid-Open Patent Application Publication No. 2022-048089

### SUMMARY

According to an embodiment, a plasma processing apparatus includes a plasma processing chamber; an electrostatic chuck disposed in the plasma processing chamber, the electrostatic chuck including a dielectric member including a substrate support surface and a ring support surface, a plurality of chuck electrodes disposed under the substrate support surface in the dielectric member, and a plurality of chuck electrodes disposed under the ring support surface in the dielectric member; and an alternating current (AC) voltage generator configured to apply AC voltages to the plurality of chuck electrodes disposed under the ring support surface, the AC voltages being phase-shifted relative to each other. The plurality of chuck electrodes disposed under the ring support surface include one chuck electrode and another chuck electrode. The one chuck electrode includes a plurality of arc portions. The another chuck electrode includes a plurality of arc portions. The arc portions of the one chuck electrode and the arc portions of the another chuck electrode are arranged alternately in a radial direction. The plurality of chuck electrodes disposed under the substrate support surface have a spiral shape and the plurality of chuck electrodes disposed under the ring support surface have a nested structure.

### BRIEF DESCRIPTION OF THE DRAWINGS

FIG. 1 is an example of a diagram for explaining a configuration example of a capacitively coupled plasma processing apparatus;

FIG. 2 is a plan view illustrating an example of an arrangement of electrostatic electrodes in an electrostatic chuck;

FIG. 3 is a plan view illustrating another example of the arrangement of the electrostatic electrodes in the electrostatic chuck;

FIG. 4 is a plan view illustrating yet another example of the arrangement of the electrostatic electrodes in the electrostatic chuck;

FIG. 5A is a graph indicating an example of a two-phase AC voltage;

FIG. 5B is a graph indicating an example of the two-phase AC voltage;

FIG. 6A is an example of a schematic cross-sectional view illustrating residual attraction of an edge ring;

FIG. 6B is an example of a schematic cross-sectional view illustrating the residual attraction of the edge ring;

FIG. 7 is a graph indicating a test result when a direct current (DC) voltage is applied to an electrostatic electrode;

FIG. 8 is a graph indicating a test result when an AC voltage is applied to the electrostatic electrode;

FIG. 9 is a flowchart illustrating an example of an edge ring replacement process;

FIG. 10 is a flowchart illustrating an example of a substrate attraction process;

FIG. 11 is a time chart illustrating an example of the substrate attraction process;

FIG. 12 is a flowchart illustrating an example of a substrate attraction release process;

FIG. 13 is a time chart illustrating an example of the substrate attraction release process;

FIG. 14 is a time chart illustrating another example of the substrate attraction release process;

FIG. 15 is an example of a cross-sectional view of an electrostatic chuck and an edge ring according to one embodiment;

FIG. 16 is a graph indicating an example of the AC voltage applied to the electrostatic electrode;

FIG. 17 is an example of a cross-sectional view of an electrostatic chuck and an edge ring according to another embodiment;

FIG. 18 is an example of a cross-sectional view of an electrostatic chuck and an edge ring according to another embodiment;

FIG. 19 is an example of a cross-sectional view of the electrostatic chuck and the edge ring according to the embodiment;

FIG. 20 is an example of a cross-sectional view of the electrostatic chuck and the edge ring according to the embodiment;

FIG. 21 is an example of a partially enlarged view of an annular region of the electrostatic chuck;

FIG. 22 is an example of a cross-sectional view of the electrostatic chuck and the edge ring cut at B-B;

FIG. 23 is an example of a cross-sectional view of the electrostatic chuck and the edge ring cut at C-C;

FIG. 24 is an example of a partially enlarged view of an annular region of the electrostatic chuck;

FIG. 25 is an example of a cross-sectional view of the electrostatic chuck and the edge ring cut at D-D;

FIG. 26 is an example of a cross-sectional view of the electrostatic chuck and the edge ring cut at E-E;

FIG. 27 is a plan view of yet another example of the arrangement of electrostatic electrodes in the electrostatic chuck;

FIG. 28 is a plan view of yet another example of the arrangement of electrostatic electrodes in the electrostatic chuck;

FIG. 29 is a graph indicating a relationship between a voltage and a heat transfer gas flow;

FIG. 30A is an example of a temperature change in the edge ring;

FIG. 30B is an example of the temperature change in the edge ring;

FIG. 30C is an example of the temperature change in the edge ring;

FIG. 31 is an example of a partially enlarged cross-sectional view of a substrate support and a graph indicating a relationship between the electric potential and a wafer attraction force;

FIG. 32 is a graph indicating a wafer attraction force in an example of plasma processing;

FIG. 33 is a graph indicating a wafer attraction force in an example of the plasma processing;

FIG. 34 is an example of a partially enlarged cross-sectional view of the substrate support and a view illustrating a relationship between the electric potential and the wafer attraction force;

FIG. 35 is a graph indicating a wafer attraction force in an example of the plasma processing;

FIG. 36 is an example of a partially enlarged cross-sectional view of the substrate support and a view illustrating the relationship between the electric potential and the wafer attraction force; and

FIG. 37 is an example of a partially enlarged cross-sectional view of the substrate support and a view illustrating the relationship between the electric potential and the wafer attraction force.

### DETAILED DESCRIPTION

According to one aspect, a plasma processing apparatus and a substrate attraction method that can suitably perform electrostatic attraction can be provided.

Various exemplary embodiments will be described in detail below with reference to the drawings. Here, the same reference numerals will be assigned to the same or corresponding parts in the drawings.

### Plasma Processing System

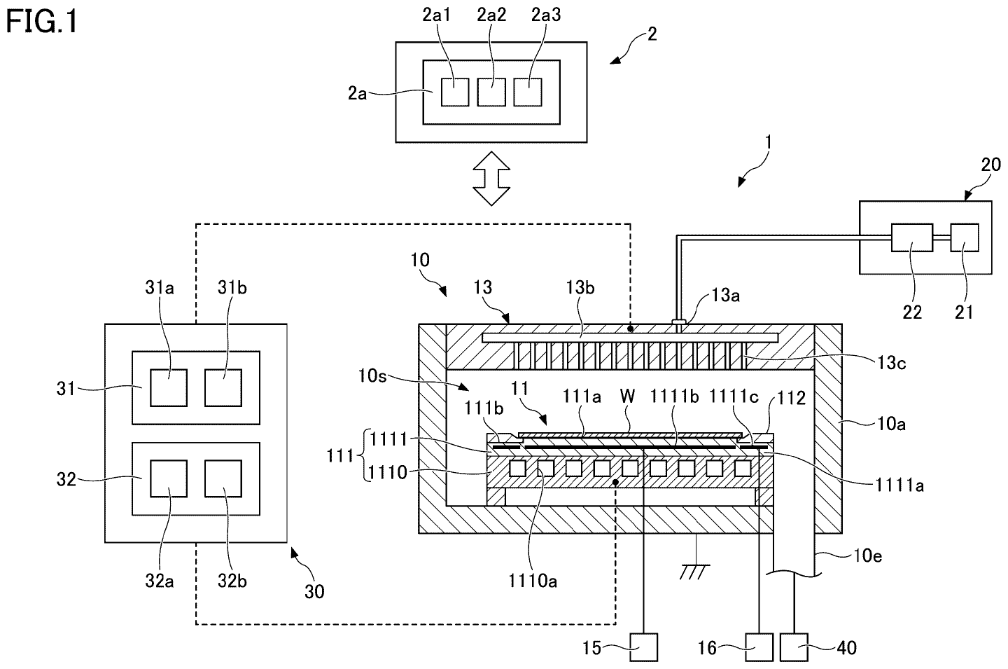

A configuration example of a plasma processing system will be described below. FIG. 1 is an example of a diagram for explaining a configuration example of a capacitively coupled plasma processing apparatus (a substrate processing apparatus) 1.

The plasma processing system includes the capacitively coupled plasma processing apparatus 1 and a controller 2. The capacitively coupled plasma processing apparatus 1 includes a plasma processing chamber 10, a gas supply 20, a power supply 30, and an exhaust system 40. Additionally, the plasma processing apparatus 1 includes a substrate support 11 and a gas introduction section. The gas introduction section is configured to introduce at least one processing gas into the plasma processing chamber 10. The gas introduction section includes a showerhead 13. The substrate support 11 is disposed in the plasma processing chamber 10. The showerhead 13 is disposed above the substrate support 11. In one embodiment, the showerhead 13 constitutes at least a portion of a ceiling of the plasma processing chamber 10. The plasma processing chamber 10 includes a plasma processing space 10s defined by the showerhead 13, a sidewall 10a of the plasma processing chamber 10, and the substrate support 11. The plasma processing chamber 10 includes at least one gas supply port for supplying at least one processing gas to the plasma processing space 10s, and at least one gas discharge port for discharging the gas from the plasma processing space 10s. The plasma processing chamber 10 is grounded. The showerhead 13 and the substrate support 11 are electrically isolated from a housing of the plasma processing chamber 10.

The substrate support 11 includes a body 111 and a ring assembly 112. The body 111 includes a central region 111a for supporting the substrate W and an annular region 111b for supporting the ring assembly 112. A wafer is an example of the substrate W. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also referred to as a substrate support surface for supporting the substrate W, and the annular region 111b is also referred to as a ring support surface for supporting the ring assembly 112.

In one embodiment, the body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member (a dielectric member) 1111a, an electrostatic electrode 1111b disposed in the ceramic member 1111a, and an electrostatic electrode 1111c disposed in the ceramic member 1111a. The ceramic member 1111a includes the central region 111a. In one embodiment, the ceramic member 1111a also includes the annular region 111b.

The ceramic member (dielectric member) 1111a includes the substrate support surface (the central region 111a) and the ring support surface (the annular region 111b).

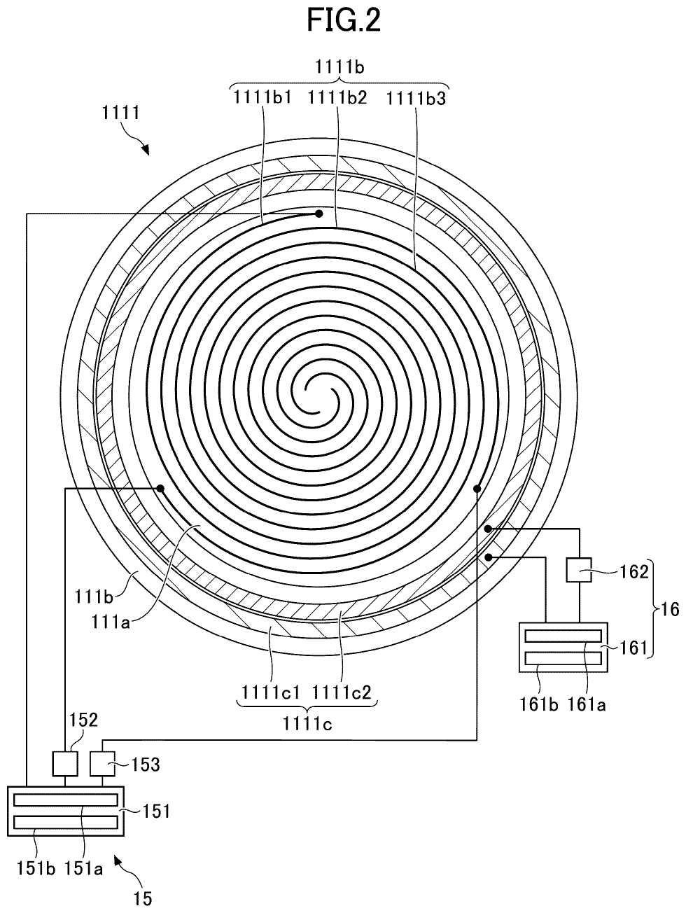

The electrostatic electrode 1111b is disposed under the central region 111a in the ceramic member 1111a. The electrostatic electrode 1111b includes N chuck electrodes (chuck electrodes 1111b1 to 1111b3 illustrated in FIG. 2, which will be described later) (N is an integer greater than or equal to 2). The plasma processing apparatus 1 includes a chuck power supply (an AC voltage generator) 15 configured to apply a voltage to each of the N chuck electrodes. The chuck power supply 15 respectively applies, to the N chuck electrodes, N-phase AC voltages phase-shifted relative to each other. The N chuck electrodes are electrically connected to the chuck power supply 15. Thus, the electrostatic chuck 1111 includes first to Nth (N is an integer greater than or equal to 2) chuck electrodes 1111b1 to 1111b3 disposed under the substrate support surface (the central region 111a) in the ceramic member 1111a. The chuck power supply 15 is configured to respectively apply first to Nth AC voltages to the first to Nth chuck electrodes 1111b1 to 1111b3. The first to Nth AC voltages are phase-shifted relative to each other.

The electrostatic electrode 1111c is disposed under the annular region 111b in the ceramic member 1111a. The electrostatic electrode 1111c includes N (N is an integer greater than or equal to 2) chuck electrodes (chuck electrodes 1111c1 to 1111c2 illustrated in FIG. 2, which will be described later). The plasma processing apparatus 1 includes a chuck power supply (an AC voltage generator) 16 configured to apply a voltage to each of the N chuck electrodes. The chuck power supply 16 applies, to the N chuck electrodes, N-phase AC voltages phase-shifted relative to each other. The N chuck electrodes are electrically connected to the chuck power supply 16. Thus, the electrostatic chuck 1111 includes the first to Nth chuck electrodes 1111c1 to 1111c2 (where N is an integer greater than or equal to 2) disposed under the ring support surface (the annular region 111b) in the ceramic member 1111a. The chuck power supply 16 is configured to respectively apply the first to Nth AC voltages to the first to Nth chuck electrodes 1111c1 to 1111c2. The first to Nth AC voltages are phase-shifted relative to each other.

Here, the following description assumes that the electrostatic electrodes 1111b and 1111c each include a plurality of electrodes, but the configuration of the electrostatic chuck 1111 is not limited thereto. One of the electrostatic electrode 1111b or the electrostatic electrode 1111c may have a single-pole configuration. Additionally, one of the electrostatic electrode 1111b or the electrostatic electrode 1111c may have a configuration in which a direct current (DC) voltage is applied.

Here, another member surrounding the electrostatic chuck 1111, such as an annular electrostatic chuck or an annular insulating member, may include the annular region 111b. In this case, the ring assembly 112 may be disposed on the annular electrostatic chuck or annular insulating member, and may be disposed on both the electrostatic chuck 1111 and the annular insulating member. Additionally, at least one RF/DC electrode coupled to a radio frequency (RF) power supply 31, a direct current (DC) power supply 32, or both described later may be disposed in the ceramic member 1111a. In this case, at least one RF/DC electrode functions as a lower electrode. When a RF bias signal, a DC signal, or both described later are supplied to at least one RF/DC electrode, the RF/DC electrode is also referred to as a bias electrode. Here, the conductive member of the base 1110 and at least one RF/DC electrode may function as a plurality of lower electrodes. Additionally, the electrostatic electrode 1111b may function as a lower electrode. Thus, the substrate support 11 includes at least one lower electrode.

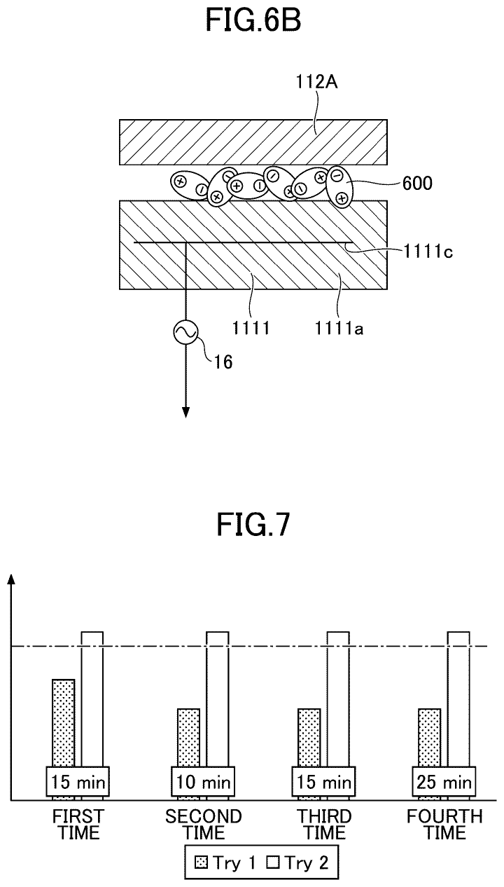

The ring assembly 112 includes one or more annular members. In one embodiment, the one or more annular members include one or more edge rings 112A (see FIGS. 6A and 6B) and at least one covering. The edge ring 112A is formed of a conductive or insulating material, and the covering is formed of an insulating material.

Additionally, the substrate support 11 may include a temperature adjust module configured to adjust at least one of the electrostatic chuck 1111, the ring assembly 112, or the substrate W to a target temperature. The temperature adjust module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or more heaters are disposed in the ceramic member 1111a of the electrostatic chuck 1111. Additionally, the substrate support 11 may include a first heat transfer gas supply configured to supply a heat transfer gas to a gap between a back surface of the substrate W and the central region 111a. The first heat transfer gas supply provides the heat transfer gas to the gap between the back surface of the substrate W and the central region 111a through a gas flow path penetrating through the base 1110 and a supply port penetrating through the electrostatic chuck 1111.

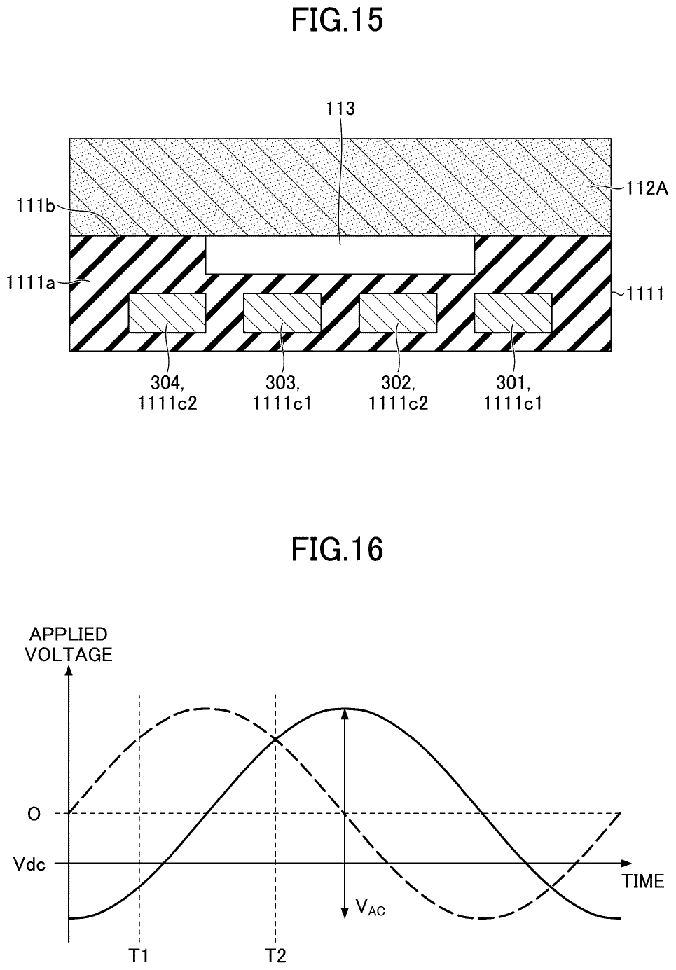

Additionally, the substrate support 11 may include a second heat transfer gas supply configured to supply a heat transfer gas to a gap between a back surface of the edge ring 112A (see FIG. 15 below) of the ring assembly 112 and the annular region 111b. The second heat transfer gas supply supplies the heat transfer gas to the gap (including a diffusion groove 113 described later in FIG. 15 and the like) between the back surface of the edge ring 112A of the ring assembly 112 and the annular region 111b through a gas path penetrating through the base 1110 and a supply port penetrating through the electrostatic chuck 1111.

The showerhead 13 is configured to introduce at least one processing gas from the gas supply 20 into the plasma processing space 10s. The showerhead 13 includes at least one gas supply port 13a, at least one gas diffusion chamber 13b, and a plurality of gas inlet ports 13c. The processing gas supplied to the gas supply port 13a is introduced into the plasma processing space 10s from the plurality of gas inlet ports 13c through the gas diffusion chamber 13b. Additionally, the showerhead 13 includes at least one upper electrode. Here, the gas introduction section may include one or more side gas injectors (SGIs) attached to one or more openings formed in the sidewall 10a, in addition to the showerhead 13.

The gas supply 20 may include at least one gas source 21 and at least one flow controller 22. In one embodiment, the gas supply 20 is configured to supply at least one processing gas from the corresponding gas source 21 to the showerhead 13 via the corresponding flow controller 22. The flow controller 22 may include, for example, a mass flow controller or a pressure-controlled flow controller. Further, the gas supply 20 may include one or more flow modulation devices configured to modulate or pulse the flow of at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode, at least one upper electrode, or both. With this, a plasma is formed from at least one processing gas supplied to the plasma processing space 10s. Thus, the RF power supply 31 may function as at least a part of a plasma generator configured to generate a plasma from one or more processing gases in the plasma processing chamber 10. Additionally, by supplying the RF bias signal to at least one lower electrode, a bias electric potential is generated in the substrate W, and ion components in the formed plasma can be drawn into the substrate W.

In one embodiment, the RF power supply 31 includes a first RF generator 31a and a second RF generator 31b. The first RF generator 31a is coupled to at least one lower electrode, at least one upper electrode, or both via at least one impedance matching circuit, and is configured to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode, at least one upper electrode, or both.

The second RF generator 31b is coupled to at least one lower electrode via at least one impedance matching circuit, and is configured to generate a RF bias signal (RF bias power). The frequency of the RF bias signal may be the same as or different from the frequency of the source RF signal. In one embodiment, the RF bias signal has a frequency lower than the frequency of the source RF signal. In one embodiment, the RF bias signal has a frequency in the range of 100 kHz to 60 MHz. In one embodiment, the second RF generator 31b may be configured to generate a plurality of RF bias signals having different frequencies. The generated one or more RF bias signals are supplied to at least one lower electrode. Additionally, in various embodiments, at least one of the source RF signal or the RF bias signal may be pulsed.

Additionally, the power supply 30 may include the DC power supply 32 coupled to the plasma processing chamber 10. The DC power supply 32 includes a first DC generator 32a and a second DC generator 32b. In one embodiment, the first DC generator 32a is connected to at least one lower electrode and is configured to generate a first DC signal. The generated first DC signal is applied to at least one lower electrode. In one embodiment, the second DC generator 32b is connected to at least one upper electrode and is configured to generate a second DC signal. The generated second DC signal is applied to at least one upper electrode.

In various embodiments, at least one of the first DC signal or the second DC signal may be pulsed. In this case, a sequence of voltage pulses is applied to at least one lower electrode, at least one upper electrode, or both. The voltage pulses may have a rectangular waveform, a trapezoidal waveform, a triangular waveform, or a combination of these pulse waveforms. In one embodiment, a waveform generator for generating a sequence of voltage pulses from the DC signal is connected between the first DC generator 32a and at least one lower electrode. Thus, the first DC generator 32a and the waveform generator constitute a voltage pulse generator. When the second DC generator 32b and the waveform generator constitute the voltage pulse generator, the voltage pulse generator is connected to at least one upper electrode. The voltage pulses may have positive polarity or negative polarity. Additionally, the sequence of voltage pulses may include one or more positive polarity voltage pulses and one or more negative polarity voltage pulses in one cycle. Here, the first and second DC generators 32a and 32b may be provided in addition to the RF power supply 31, and the first DC generator 32a may be provided instead of the second RF generator 31b.

The exhaust system 40 may be connected, for example, to a gas discharge port 10e provided at the bottom of the plasma processing chamber 10. The exhaust system 40 may include a pressure regulating valve and a vacuum pump. The pressure regulating valve regulates the pressure in the plasma processing space 10s. The vacuum pump may include a turbomolecular pump, a dry pump, or a combination thereof.

The controller 2 processes computer-executable instructions that cause the plasma processing apparatus 1 to perform the various steps described in the present disclosure. The controller 2 may be configured to control elements of the plasma processing apparatus 1 to perform the various steps described herein. In one embodiment, part or all of the controller 2 may be included in the plasma processing apparatus 1. The controller 2 may include a processing unit 2a1, a storage unit 2a2, and a communication interface 2a3. The controller 2 may be implemented by, for example, a computer 2a. The processing unit 2a1 may be configured to read a program from the storage unit 2a2 and execute the read program to perform various control operations. The program may be stored in the storage unit 2a2 in advance or may be acquired via a medium when necessary. The acquired program is stored in the storage unit 2a2 and is read from the storage unit 2a2 and executed by the processing unit 2a1. The medium may be various storage media readable by the computer 2a or a communication line connected to the communication interface 2a3. The processing unit 2a1 may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a LAN (Local Area Network).

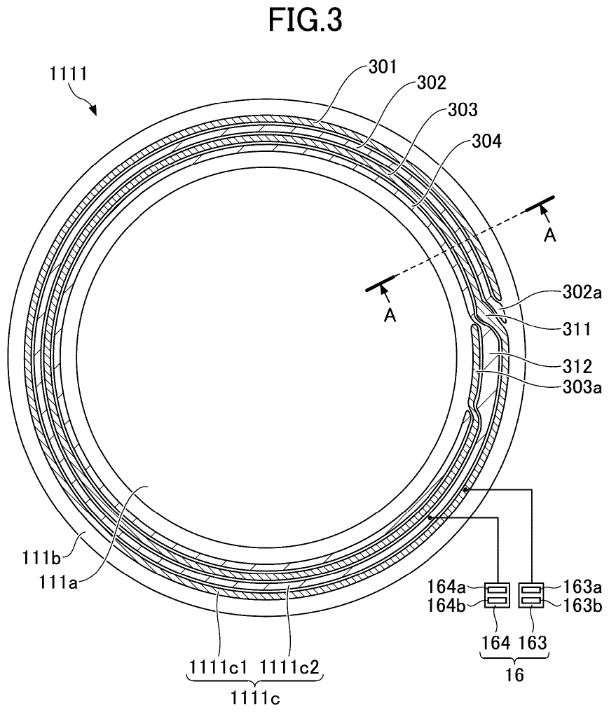

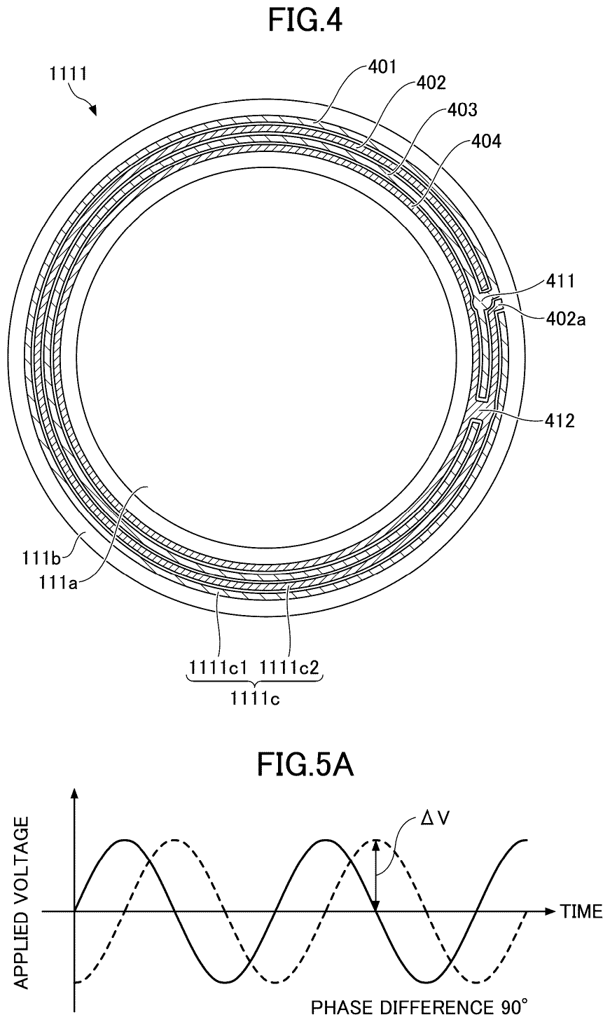

Next, an example of the electrostatic chuck 1111 will be described with reference to FIGS. 2 to 4. FIG. 2 is a plan view illustrating an example of an arrangement of the electrostatic electrodes 1111b and 1111c of the electrostatic chuck 1111. FIG. 3 is a plan view illustrating another example of the arrangement of the electrostatic electrode 1111c of the electrostatic chuck 1111. FIG. 4 is a plan view illustrating yet another example of the arrangement of the electrostatic electrode 1111c of the electrostatic chuck 1111. Here, in FIG. 2, the electrostatic electrode 1111b is described with an example of a 3-pole (N=3) configuration. In FIGS. 3 and 4, illustration of the electrostatic electrode 1111b disposed under the central region 111a is omitted. In FIGS. 2 to 4, the electrostatic electrode 1111c is described with an example of a 2-pole (N=2) configuration. In FIGS. 2 to 4, the electrostatic electrode 1111c is indicated by hatching.

In the example of the electrostatic chuck 1111 illustrated in FIG. 2, the electrostatic electrode 1111c includes a first chuck electrode 1111c1 and a second chuck electrode 1111c2. The first chuck electrode 1111c1 and the second chuck electrode 1111c2 are formed in a concentric annular shape.

The chuck power supply 16 includes a power supply 161 and a phase adjuster 162. The power supply 161 applies an AC voltage (a first AC voltage) to the first chuck electrode 1111c1. Here, the power supply 161 includes an AC power supply 161a and a DC power supply 161b. The AC power supply 161a generates the AC voltage and applies it to the first chuck electrode 1111c1. The DC power supply 161b generates a DC voltage and superimposes it on the AC voltage applied to the first chuck electrode 1111c1. Here, the power supply 161 may be configured to include only one of the AC power supply 161a or the DC power supply 161b. Additionally, the phase adjuster 162 is electrically connected between the power supply 161 and the second chuck electrode 1111c2. The phase adjuster 162 phase-shifts the AC voltage supplied from the power supply 161 and supplies the phase-shifted AC voltage (a second AC voltage) to the second chuck electrode 1111c2.

In the example of the electrostatic chuck 1111 illustrated in FIG. 2, the electrostatic electrode 1111b includes a first chuck electrode 1111b1, a second chuck electrode 1111b2, and a third chuck electrode 1111b3. The first chuck electrode 1111b1, the second chuck electrode 1111b2, and the third chuck electrode 1111b3 are formed in a spiral shape.

The chuck power supply 15 includes a power supply 151 and phase adjusters 152 and 153. The power supply 151 applies an AC voltage (a first AC voltage) to the first chuck electrode 1111b1. Here, the power supply 151 includes an AC power supply 151a and a DC power supply 151b. The AC power supply 151a generates the AC voltage and applies it to the first chuck electrode 1111b1. The DC power supply 151b generates a DC voltage and superimposes it on the AC voltage applied to the first chuck electrode 1111b1. Here, the power supply 151 may be configured to include only one of the AC power supply 151a or the DC power supply 151b. Additionally, the phase adjuster 152 is connected between the power supply 151 and the second chuck electrode 1111b2. The phase adjuster 152 phase-shifts the AC voltage supplied from the power supply 151 and supplies the phase-shifted AC voltage (a second AC voltage) to the second chuck electrode 1111b2. Additionally, the phase adjuster 153 is connected between the power supply 151 and the third chuck electrode 1111b3. The phase adjuster 153 phase-shifts the AC voltage supplied from the power supply 151 and supplies the phase-shifted AC voltage (a third AC voltage) to the third chuck electrode 1111b3.

In another example of the electrostatic chuck 1111 illustrated in FIG. 3, the electrostatic electrode 1111c includes the first chuck electrode 1111c1 and the second chuck electrode 1111c2. The first chuck electrode 1111c1 and the second chuck electrode 1111c2 are formed in a spiral shape. The electrostatic electrode 1111c has a first arc portion 301, a second arc portion 302, a third arc portion 303, and a fourth arc portion 304 in order in the radial direction from the outer peripheral side to the center side. Additionally, the electrostatic electrode 1111c includes a first connection 311 that connects the first arc portion 301 to the third arc portion 303, and a second connection 312 that connects the second arc portion 302 to the fourth arc portion 304.

The first chuck electrode 1111c1 includes the first arc portion 301, the first connection 311, and the third arc portion 303. The second chuck electrode 1111c2 includes the second arc portion 302, the second connection 312, and the fourth arc portion 304.

In the second chuck electrode 1111c2, the second arc portion 302 includes an extension 302a extending to the first arc portion 301 side. With this, with respect to the first connection 311, the extension 302a of the second chuck electrode 1111c2, the second arc portion 302 of the second chuck electrode 1111c2, or both are disposed on the outer peripheral side, and the second connection 312 of the second chuck electrode 1111c2, the fourth arc portion 304 of the second chuck electrode 1111c2, or both are disposed on the inner peripheral side.

Additionally, in the first chuck electrode 1111c1, the third arc portion 303 includes an extension 303a extending to the fourth arc portion 304 side. With this, with respect to the second connection 312, the first arc portion 301 of the first chuck electrode 1111c1, the first connection 311 of the first chuck electrode 1111c1, or both are disposed on the outer peripheral side, and the extension 303a is disposed on the inner peripheral side.

Here, in the first chuck electrode 1111c1, the first connection 311 connects one end of the first arc portion 301 to one end of the third arc portion 303. In the second chuck electrode 1111c2, the second connection 312 connects one end of the second arc portion 302 to one end of the fourth arc portion 304. With this, the first chuck electrode 1111c1 and the second chuck electrode 1111c2 are formed in a spiral shape.

The chuck power supply 16 includes a first power supply 163 and a second power supply 164. The first power supply 163 applies the AC voltage (the first AC voltage) to the first chuck electrode 1111c1. Here, the power supply 163 includes an AC power supply 163a and a DC power supply 163b. The AC power supply 163a generates the AC voltage and applies it to the first chuck electrode 1111c1. The DC power supply 163b generates a DC voltage and superimposes it on the AC voltage applied to the first chuck electrode 1111c1. Here, the power supply 163 may be configured to include only one of the AC power supply 163a or the DC power supply 163b. Additionally, the second power supply 164 applies the AC voltage (the second AC voltage) to the second chuck electrode 1111c2. Here, the power supply 164 includes an AC power supply 164a and a DC power supply 164b. The AC power supply 164a generates the AC voltage and applies it to the second chuck electrode 1111c2. The DC power supply 164b generates a DC voltage and superimposes it on the AC voltage applied to the second chuck electrode 1111c2. Here, the power supply 164 may be configured to include only one of the AC power supply 164a or the DC power supply 164b. Further, the AC voltage of the second power supply 164 (the AC power supply 164a) is phase-shifted with respect to the AC voltage of the first power supply 163 (the AC power supply 163a).

In yet another example of the electrostatic chuck 1111 illustrated in FIG. 4, the electrostatic electrode 1111c includes the first chuck electrode 1111c1 and the second chuck electrode 1111c2. The first chuck electrode 1111c1 and the second chuck electrode 1111c2 are formed in a nested structure. The electrostatic electrode 1111c includes a first arc portion 401, a second arc portion 402, a third arc portion 403, and a fourth arc portion 404 in order in the radial direction from the outer peripheral side to the center side. Additionally, the electrostatic electrode 1111c includes a first connection 411 that connects the first arc portion 401 to the third arc portion 403, and a second connection 412 that connects the second arc portion 402 to the fourth arc portion 404.

The first chuck electrode 1111c1 includes the first arc portion 401, the first connection 411, and the third arc portion 403. The second chuck electrode 1111c2 includes the second arc portion 402, the second connection 412, and the fourth arc portion 404. Here, the fourth arc portion 404 may be formed in an annular shape as illustrated in FIG. 4.

In the second chuck electrode 1111c2, the second arc portion 402 includes an extension 402a extending to the first arc portion 401 side.

Here, in the first chuck electrode 1111c1, the first connection 411 connects an intermediate position of the first arc portion 401 (between one end of the first arc portion 401 and the other end of the first arc portion 401) to an intermediate position of the third arc portion 403 (between one end of the third arc portion 403 and the other end of the third arc portion 403). In the second chuck electrode 1111c2, the second connection 412 connects an intermediate position of the second arc portion 402 (between one end of the second arc portion 402 and the other end of the second arc portion 402) to an intermediate position of the fourth arc portion 404 (between one end of the fourth arc portion 404 and the other end of the fourth arc portion 404). With this, the first chuck electrode 1111c1 and the second chuck electrode 1111c2 are formed in a nested structure.

The electrostatic electrode 1111c illustrated in FIG. 2 may be configured such that the AC voltage is applied from the first power supply 163 and the second power supply 164 as illustrated in FIG. 3. Additionally, the electrostatic electrode 1111c illustrated in FIG. 3 may be configured such that the AC voltage is applied from the power supply 161 and the phase adjuster 162 as illustrated in FIG. 2. The electrostatic electrode 1111c illustrated in FIG. 4 may be configured such that the AC voltage is applied from the power supply 161 and the phase adjuster 162 as illustrated in FIG. 2, and may be configured such that the AC voltage is applied from the first power supply 163 and the second power supply 164 as illustrated in FIG. 3.

The electrostatic electrode 1111b illustrated in FIG. 2 has been described as being formed in a spiral shape, but the embodiment is not limited thereto. The electrostatic electrode 1111b may be formed in an annular shape (see the electrostatic electrode 1111c in FIG. 2) or a nested structure (see the electrostatic electrode 1111c in FIG. 4). In one embodiment, the first to Nth chuck electrodes 1111b1 to 1111b3 have a circular or ring shape arranged concentrically. In one embodiment, the first to Nth chuck electrodes 1111b1 to 1111b3 have a spiral shape or a nested structure. In one embodiment, the first to Nth chuck electrodes 1111c1 and 1111c2 have a ring shape arranged concentrically. In one embodiment, the first to Nth chuck electrodes 1111c1 and 1111c2 have a spiral shape or a nested structure.

Additionally, the chuck power supply 15 illustrated in FIG. 2 has been described as including the power supply 151 and the phase adjusters 152 and 153, but the embodiment is not limited thereto. Three power supplies may be configured to be electrically connected to the three chuck electrodes 1111b1 to 1111b3, respectively.

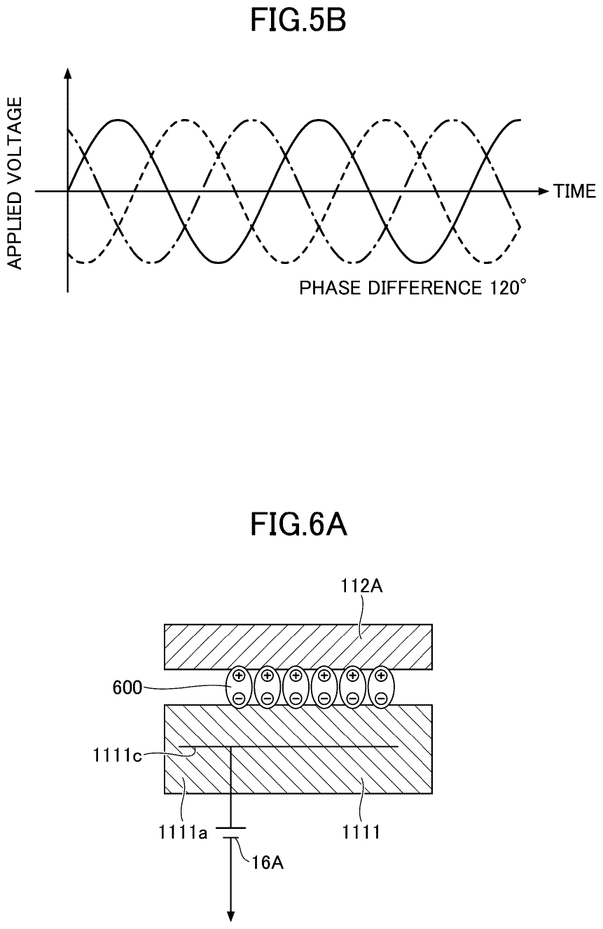

FIGS. 5A and 5B are graphs indicating examples of the AC voltage. FIG. 5A is a graph indicating an example of a two-phase AC voltage. FIG. 5B is a graph indicating an example of a three-phase AC voltage. The vertical axis indicates the applied voltage, and the horizontal axis indicates the time.

In FIG. 5A, an example of the AC voltage applied to the first chuck electrode 1111c1 is illustrated as a solid line graph, and an example of the AC voltage applied to the second chuck electrode 1111c2 is illustrated as a dashed line graph.

The AC voltages respectively applied to the electrodes (the first chuck electrode 1111c1 and the second chuck electrode 1111c2) of the electrostatic electrode 1111c by the chuck power supply 16 have the same maximum amplitude, the same frequency, and phases different to each other. For example, the phase difference between the AC voltages applied to the first chuck electrode 1111c1 and the second chuck electrode 1111c2 is set to 90°. With this, an electric potential difference ΔV is formed between the first chuck electrode 1111c1 and the second chuck electrode 1111c2. By applying the voltage in such a way, even when the number of electrodes of the electrostatic electrode 1111c is two, the attraction force of the electrostatic chuck 1111 for attracting the edge ring 112A (see FIGS. 6A and 6B) of the ring assembly 112 can be made constant.

Additionally, when the number of electrodes of the electrostatic electrode 1111c is N, the N-phase AC voltage is expressed by the following equation (1), when the amplitude is A and the frequency is f. Here, n is an individual integer corresponding to an electrode among N electrodes. FIG. 5B indicates an example of a three-phase AC voltage.

A sin(2πft+n/N×360°) (1)

Additionally, the phase difference between one electrode and another electrode on the inner peripheral side is (1/N×360°), and the phase difference between one electrode and another electrode on the outer peripheral side is (1/N×360°). Thus, the electric potential difference between adjacent electrodes can be reduced. With this, short-circuiting between the electrodes can be suppressed.

In other words, the distance between the electrodes can be narrowed, and the area (the width in the radial direction) of the electrodes can be widened. With this, the proportion occupied by the electrostatic electrode 1111c on the ring support surface (the annular region 111b) can be increased. Here, the attraction force is generated at a position where the electrodes are formed, and the attraction force is not generated in an insulating region between the electrodes. According to the electrostatic chuck 1111, the attraction force of the edge ring 112A can be improved by widening the area of the electrodes. Additionally, the in-plane uniformity of the attraction force can be improved. Here, although the electrostatic electrode 1111c for attracting the edge ring 112A has been described as an example, the same applies to the electrostatic electrode 1111b for attracting the substrate W.

Next, the electrostatic attraction of the edge ring 112A will be described with reference to FIGS. 6A and 6B. FIGS. 6A and 6B are examples of a schematic cross-sectional view illustrating residual attraction of the edge ring 112A.

FIG. 6A illustrates a case where a DC voltage is applied to the electrostatic electrode 1111c from a DC power supply 16A. Here, due to the cleaning of the edge ring 112A, the storage of the edge ring 112A in an atmospheric atmosphere, or the like, water molecules 600 may adhere to a back surface (a contact surface with the ring support surface) of the edge ring 112A. As illustrated in the configuration of FIG. 6A, when the DC voltage is applied to the electrostatic electrode 1111c, the water molecules 600 are aligned and polarized so as to form an electric field in a direction opposite to that of the electric field formed between the electrostatic electrode 1111c and the edge ring 112A. This effectively weakens the attraction force between the edge ring 112A and the electrostatic chuck 1111.

Additionally, after the DC voltage application from the DC power supply 16A to the electrostatic electrode 1111c is stopped, adsorption (residual attraction) occurs due to the dipole moment of the water molecules 600. With this, there is a possibility that the edge ring 112A cannot be removed from the electrostatic chuck 1111 until the residual attraction is reduced.

FIG. 6B illustrates a case where an AC voltage is applied from the chuck power supply 16 to the electrostatic electrode 1111c. The chuck power supply 16 applies, to the electrostatic electrode 1111c, an AC voltage having a frequency faster than the polarization rate of the water molecules 600, specifically a frequency within the range of 0.01 Hz to 100 Hz. Thus, the time-averaged electric field becomes zero, and the polarization of the water molecules 600 can be suppressed. With this, decrease in the attraction force between the edge ring 112A and the electrostatic chuck 1111 due to the polarization of the water molecules 600 can be suppressed. Additionally, the residual attraction due to the polarization of the water molecules 600 can be suppressed.

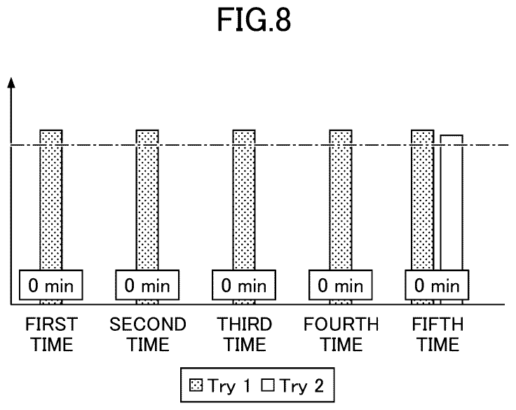

Here, simulation test results about the attraction force of the edge ring 112A will be described with reference to FIGS. 7 to 8.

FIG. 7 indicates the test results when the DC voltage was applied to the electrostatic electrode 1111c. Here, the edge ring 112A was mounted on the ring support surface of the electrostatic chuck 1111, and the DC voltage was applied from the DC power supply 16A to the electrostatic electrode 1111c. Then, the attraction force was measured. The first measured attraction force (Try1) is illustrated by a shaded bar graph. When the attraction force was less than a reference value (illustrated by a dashed line in FIG. 7), the polarity of the DC voltage applied from the DC power supply 16A to the electrostatic electrode 1111c were reversed three times to eliminate the polarization of the water molecules 600, and then the attraction force was measured again. The second measured attraction force (Try2) is illustrated by a blank bar graph.

Next, the DC voltage applied to the electrostatic electrode 1111c was stopped, and it was measured whether the edge ring 112A could be lifted from the electrostatic chuck 1111. If it could not be lifted, the measurement was performed every 5 minutes. The time until it can be lifted (in other words, the time until residual attraction is sufficiently reduced) is also indicated.

The above tests were performed four times.

As illustrated in FIG. 7, in the case of the attraction performed by the DC voltage, it is confirmed the first measured attraction force (Try1) is often less than the reference value (indicated by the dashed line in FIG. 7). Additionally, the second measured attraction force after reversing the polarity of the DC voltage three times (Try2) exceeds the reference value, which indicates that the attraction was suitably performed.

FIG. 8 illustrates the test results when the AC voltage was applied to the electrostatic electrode 1111c. Here, the edge ring 112A was mounted on the ring support surface of the electrostatic chuck 1111, and the AC voltage was applied to the electrostatic electrode 1111c from the chuck power supply 16. Then, the attraction force was measured.

Next, the AC voltage applied to the electrostatic electrode 1111c was stopped, and it was measured whether the edge ring 112A could be lifted from the electrostatic chuck 1111. If it could not be lifted, the measurement was performed every five minutes. The time until it can be lifted (in other words, the time until residual attraction is sufficiently reduced) is also indicated.

The above tests were performed five times.

As illustrated in FIG. 8, in the case of the attraction performed by the AC voltage, it is confirmed that the first measured attraction force exceeds the reference value (indicated by a dashed line in FIG. 8).

Additionally, in the case of the attraction performed by the AC voltage, the edge ring 112A can be lifted without any waiting time (zero minutes). That is, it is confirmed that residual attraction was sufficiently reduced.

### Edge Ring 112A Replacement Process

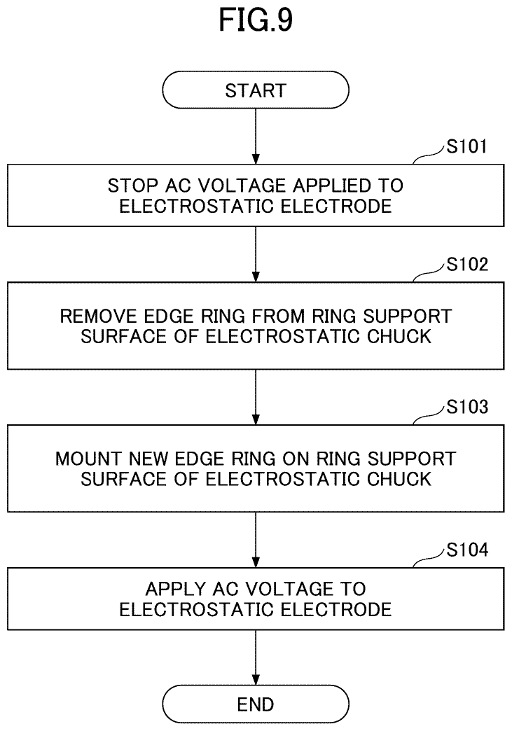

Next, a process of replacing the edge ring 112A (an edge ring replacement sequence) will be described with reference to FIG. 9. FIG. 9 is a flowchart illustrating an example of the process of replacing the edge ring 112A. Here, a case where a used edge ring (a first edge ring) 112A mounted on the ring support surface of the electrostatic chuck 1111 is replaced with an unused edge ring (a second edge ring) 112A′ will be described.

Here, at the start of the replacement process, it is assumed that the used edge ring (the first edge ring) 112A is mounted on the ring support surface of the electrostatic chuck 1111, an AC voltage is applied to the electrostatic electrode 1111c, and the used edge ring 112A is attracted to the electrostatic chuck 1111.

In step S101, the controller 2 controls the chuck power supply 16 to stop the AC voltage applied to the electrostatic electrode 1111c.

In step S102, the controller 2 removes the used edge ring 112A from the ring support surface of the electrostatic chuck 1111. For example, the controller 2 controls the transfer device (not illustrated) to remove the used edge ring 112A from the ring support surface of the electrostatic chuck 1111, and carries the used edge ring 112A out of the plasma processing chamber 10. Here, as illustrated in FIG. 8, by using the AC voltage as the voltage applied to the electrostatic electrode 1111c, residual attraction can be suppressed. Thus, the waiting time until the residual attraction force is reduced can be reduced or eliminated, and the used edge ring 112A can be removed.

In step S103, the controller 2 mounts the unused edge ring (the second edge ring) 112A′ on the ring support surface of the electrostatic chuck 1111. For example, the controller 2 controls the transfer device (not illustrated) to carry the unused edge ring 112A′ into the plasma processing chamber 10, and mounts the unused edge ring 112A′ on the ring support surface of the electrostatic chuck 1111.

In step S104, the controller 2 controls the chuck power supply 16 to apply the AC voltage to the electrostatic electrode 1111c. Here, as illustrated in FIG. 8, the unused edge ring 112A′ can be suitably attracted by a single attraction process.

Therefore, the above edge ring replacement sequence includes the following steps (a) to (d):
(a) a step of changing the first to Nth AC voltages respectively applied to the first to Nth chuck electrodes 1111c1 to 1111c2 from an ON state to an OFF state;
(b) a step of removing the first edge ring 112A arranged on the ring support surface (the annular region 111b);
(c) a step of mounting the second edge ring 112A′ on the ring support surface (the annular region 111b); and
(d) a step of changing the first to Nth AC voltages respectively applied to the first to Nth chuck electrodes 1111c1 to 1111c2 from the OFF state to the ON state.

With this, the edge ring 112A′ can be preferably electrostatically attracted. Additionally, the edge ring 112A′ continues to be electrostatically attracted until the next replacement is performed. In the configuration in which the DC voltage is applied, residual attraction may increase. By using the AC voltage, residual attraction can be suppressed.

Here, the removal of the used edge ring 112A and the mounting of the unused edge ring 112A′ in steps S102 and S103 may be performed by an operator while the plasma processing chamber 10 is opened and is open to the atmosphere.

### Substrate W Attraction Process

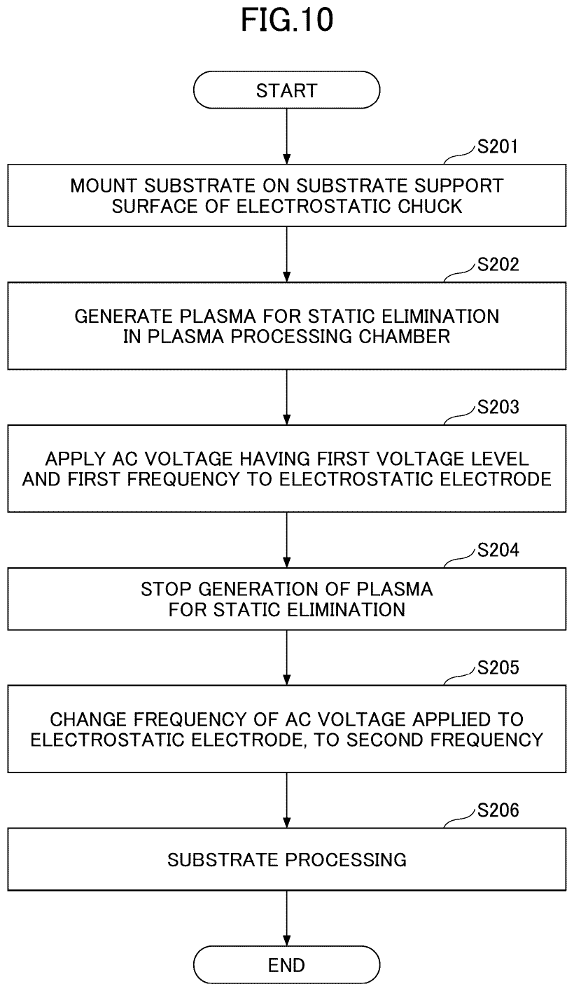

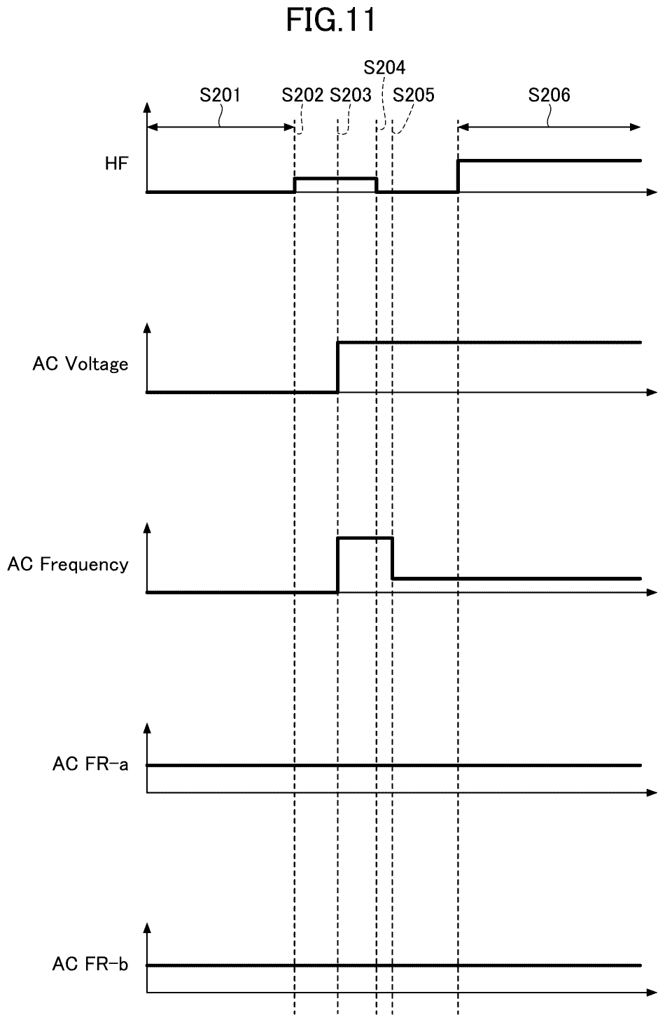

Next, an attraction process of the substrate W (a substrate chuck sequence) will be described with reference to FIGS. 10 and 11. FIG. 10 is a flowchart illustrating an example of the attraction process of the substrate W. FIG. 11 is a time chart illustrating the example of the attraction process of the substrate W. In FIG. 11, HF indicates high-frequency power for plasma generation. That is, it indicates the source RF signal (the source RF power) for plasma generation that is supplied to at least one lower electrode, at least one upper electrode, or both by the first RF generator 31a. AC Voltage indicates a voltage level (corresponding to the amplitude A in Equation (1)) of the high-frequency voltage applied to the electrostatic electrode 1111b. AC Frequency indicates the frequency (corresponding to the frequency f in Equation (1)) of the high-frequency voltage applied to the electrostatic electrode 1111b. Here, the electrostatic electrode 1111b is, for example, three-pole chuck electrodes 1111b1, 1111b2, and 1111b3 (see FIG. 2), and high-frequency voltages having a phase difference of 120° are respectively applied to the three-pole chuck electrodes 1111b1, 1111b2, and 1111b3, as illustrated in Equation (1). AC FR-a indicates a voltage level (corresponding to the amplitude A in Equation (1)) of the high-frequency voltage applied to the first chuck electrode 1111c1. AC FR-b indicates a voltage level (corresponding to the amplitude A in Equation (1)) of the high-frequency voltage applied to the second chuck electrode 1111c2. Here, in the processes illustrated in FIGS. 10 and 11, the edge ring 112A is maintained in a state of being attracted to the electrostatic chuck 1111.

At the start of the attraction process of the substrate W, it is assumed that the edge ring 112A is mounted on the ring support surface of the electrostatic chuck 1111, the AC voltages are applied to the first chuck electrode 1111c1 and the second chuck electrode 1111c2, and the edge ring 112A is attracted to the electrostatic chuck 1111.

In step S201, the controller 2 mounts the substrate W on the substrate support surface (the central region 111a) of the electrostatic chuck 1111.

In step S202, the controller 2 controls the plasma generator to generate a plasma (a first plasma) for static elimination in the plasma processing chamber 10. Here, the first RF generator 31a supplies the source RF signal (the source RF power) for plasma generation to at least one lower electrode, at least one upper electrode, or both. With this, the plasma for static elimination is generated in the plasma processing chamber 10. By the surface of the substrate W being exposed to this plasma, charges charged on the surface of the substrate W can be released.

In step S203, the controller 2 controls the chuck power supply 15 to apply the AC voltage to the electrostatic electrode 1111b. Here, the AC voltage having the first voltage level (corresponding to the amplitude A in Equation (1)) and the first frequency (corresponding to the frequency f in Equation (1)) is applied. Here, the first frequency is a frequency faster than the polarization rate of the water molecules 600, specifically, a frequency within the range of 0.01 Hz to 100 Hz.

In step S204, the controller 2 controls the plasma generator to stop the generation of plasma for static elimination in the plasma processing chamber 10.

In step S205, the controller 2 controls the chuck power supply 15 to change the frequency of the AC voltage applied to the electrostatic electrode 1111b. Here, while maintaining the first voltage level, the frequency is changed from the first frequency to a second frequency that is less than the first frequency.

In step S206, the controller 2 controls the plasma generator to generate a plasma (a second plasma) for substrate processing in the plasma processing chamber 10. Here, the first RF generator 31a supplies the source RF signal (the source RF power) for plasma generation to at least one lower electrode, at least one upper electrode, or both.

Therefore, the substrate chuck sequence described above includes the following steps (a) to (f):
(a) a step of mounting the substrate W on the substrate support surface (the central region 111a);
(b) a step of generating the first plasma in the plasma processing chamber 10;
(c) a step of respectively applying the first to Nth AC voltages to the first to Nth chuck electrodes 1111b1 to 1111b3 (the first to Nth AC voltages have the first voltage level and the first frequency, and are phase-shifted relative to each other);
(d) a step of stopping the generation of the first plasma;
(e) a step of changing the first to Nth AC voltages respectively applied to the first to Nth chuck electrodes 1111b1 to 1111b3 to the second frequency greater than the first frequency while maintaining the first voltage level; and
(f) a step of generating the second plasma in the plasma processing chamber.

With this, the plasma for substrate processing is generated in the plasma processing chamber 10. Additionally, the source RF power has the first power level in step (b), a zero power level in step (d), and the second power level greater than the first power level in step (f).

According to the processes illustrated in FIGS. 10 and 11, in step S203, the substrate W is electrostatically attracted at the first frequency that is greater than the frequency (the second frequency) of the AC voltage applied to the electrostatic electrode 1111b in the substrate processing (S206). With this, by applying, to the electrostatic electrode 1111c, the AC voltage having a frequency (for example, a frequency in the range of 0.01 Hz to 100 Hz) faster than the polarization rate of the water molecules 600 adsorbed on the surface of the substrate W, the time-averaged electric field becomes zero, and the polarization of the water molecules 600 can be suppressed. With this, a decrease in the attraction force between the edge ring 112A and the electrostatic chuck 1111 due to the polarization of the water molecules 600 can be suppressed.

Additionally, in step S205, the frequency of the AC voltage applied to the electrostatic electrode 1111b is changed to the second frequency (the first frequency>the second frequency). With this, in the substrate processing in step S206, the influence of the AC voltage applied to the electrostatic electrode 1111b on the substrate processing can be suppressed.

### Substrate W Attraction Release Process

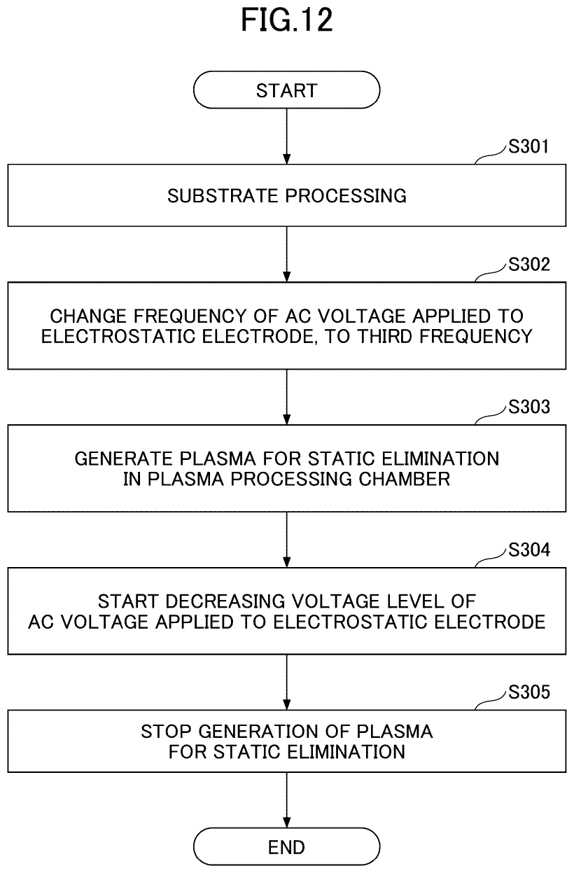

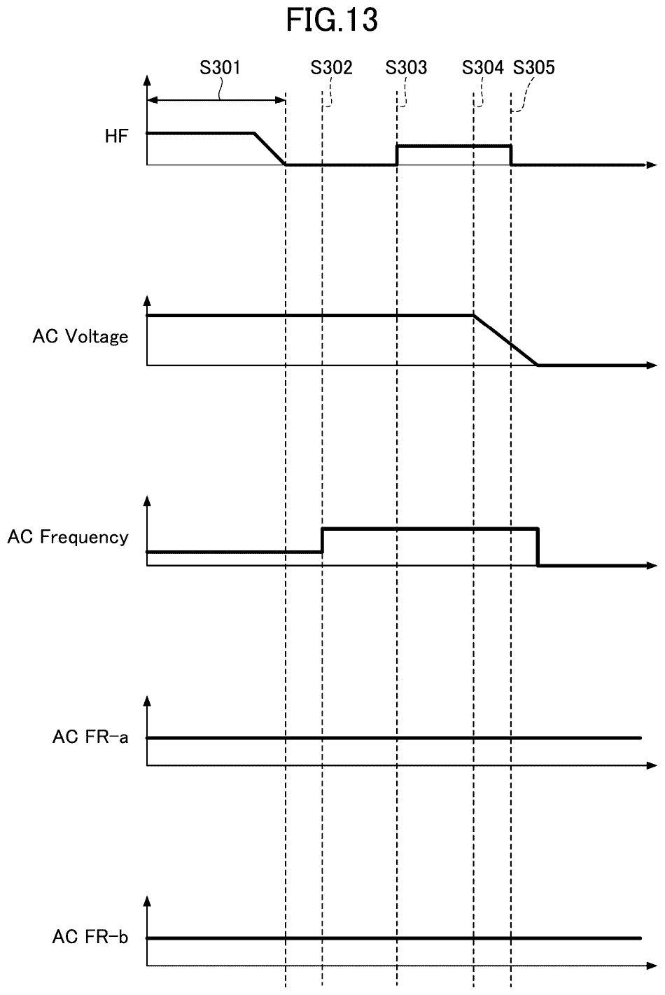

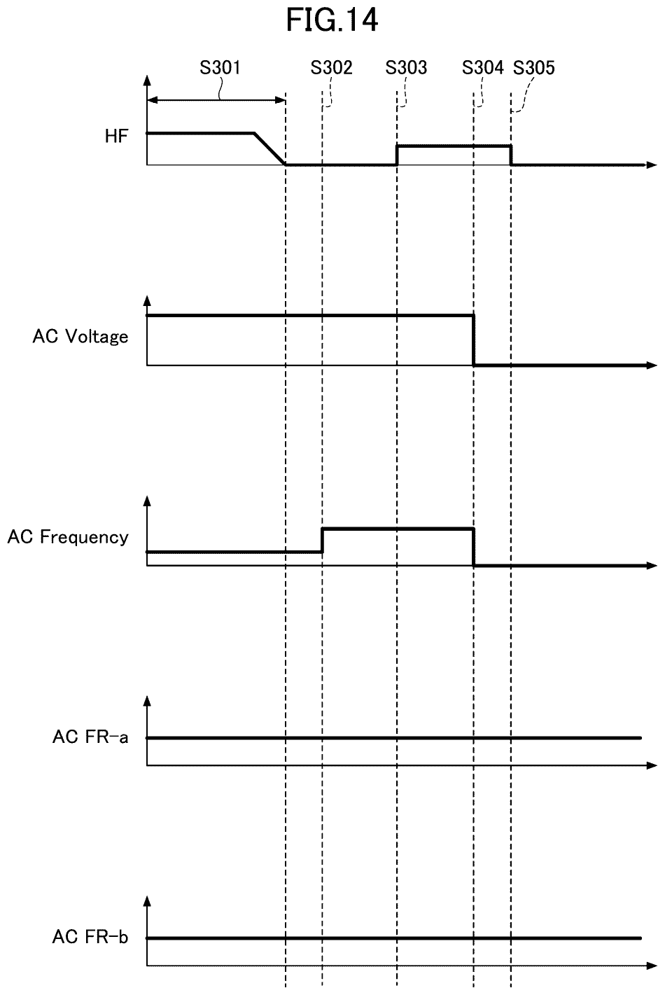

Next, a substrate W attraction release process (a substrate dechuck sequence) will be described with reference to FIGS. 12 to 14. FIG. 12 is a flowchart illustrating an example of the substrate W attraction release process. FIG. 13 is a time chart illustrating the example of the substrate W attraction release process. FIG. 14 is a time chart illustrating another example of the substrate W attraction release process. In FIGS. 13 and 14, HF indicates high-frequency power for plasma generation. That is, it indicates the source RF signal (the source RF power) for plasma generation supplied by the first RF generator 31a to at least one lower electrode, at least one upper electrode, or both. AC Voltage indicates a voltage level (corresponding to the amplitude A in Equation (1)) of the high-frequency voltage applied to the electrostatic electrode 1111b. AC Frequency indicates the frequency (corresponding to the frequency f in Equation (1)) of the high-frequency voltage applied to the electrostatic electrode 1111b. Here, the electrostatic electrode 1111b is, for example, three-pole chuck electrodes 1111b1, 1111b2, and 1111b3 (see FIG. 2), and high-frequency voltages having a phase difference of 120° as illustrated in Equation (1) are respectively applied to the three-pole chuck electrodes 1111b1, 1111b2, and 1111b3. AC FR-a indicates a voltage level (corresponding to the amplitude A in Equation (1)) of the high-frequency voltage applied to the first chuck electrode 1111c1. AC FR-b indicates a voltage level (corresponding to the amplitude A in Equation (1)) of the high-frequency voltage applied to the second chuck electrode 1111c2. Here, in the processes illustrated in FIGS. 10 and 11, the edge ring 112A maintains a state in which the edge ring 112A is attracted to the electrostatic chuck 1111.

Here, it is assumed that at the start of the substrate W attraction release process, the edge ring 112A is mounted on the ring support surface of the electrostatic chuck 1111, the AC voltages are applied to the first chuck electrode 1111c1 and the second chuck electrode 1111c2, and the edge ring 112A is attracted to the electrostatic chuck 1111. Additionally, it is assumed that the substrate W is mounted on the substrate support surface of the electrostatic chuck 1111, the AC voltages are applied to the first chuck electrode 1111b1 to the third chuck electrode 1111c3, and the substrate W is attracted to the electrostatic chuck 1111. Here, the AC voltages applied to the first chuck electrode 1111b1 to the third chuck electrode 1111c3 have the first voltage level and the second frequency.

In step S301, the controller 2 controls the plasma generator to generate the plasma (the second plasma) for substrate processing in the plasma processing chamber 10. With this, the substrate W is subjected to the plasma processing. Here, the first RF generator 31a supplies the source RF signal (the source RF power) for plasma generation to at least one lower electrode, at least one upper electrode, or both. With this, the plasma for substrate processing is generated in the plasma processing chamber 10.

In step S302, the controller 2 controls the chuck power supply 15 to change the frequency of the AC voltage applied to the electrostatic electrode 1111b. Here, while maintaining the first voltage level, the frequency is changed from the second frequency to a third frequency that is greater than the second frequency. Here, the third frequency is a frequency faster than the polarization rate of the water molecules 600, specifically, a frequency within the range of 0.01 Hz to 100 Hz.

In step S303, the controller 2 controls the plasma generator to generate a plasma (a third plasma) for static elimination in the plasma processing chamber 10. Here, the first RF generator 31a supplies the source RF signal (the source RF power) for plasma generation to at least one lower electrode, at least one upper electrode, or both. With this, the plasma for static elimination is generated in the plasma processing chamber 10. By the surface of the substrate W being exposed to this plasma, the charge charged on the surface of the substrate W can be released.

In step S304, the controller 2 controls the chuck power supply 15 to start decreasing the voltage level of the AC voltage applied to the electrostatic electrode 1111b.

In step S305, the controller 2 controls the plasma generator to stop the generation of the plasma for static elimination in the plasma processing chamber 10.

Here, as illustrated in FIG. 13, at the time of stopping the generation of the plasma illustrated in step S305, the voltage level of the AC voltage applied to the electrostatic electrode 1111b may be sufficiently reduced, and after stopping the generation of the plasma illustrated in step S305, the voltage level of the AC voltage applied to the electrostatic electrode 1111b may be set to zero.

Additionally, in FIG. 13, the illustration assumes that the voltage level of the AC voltage applied to the electrostatic electrode 1111b is continuously decreased, but the voltage level is not limited thereto. For example, the voltage level of the AC voltage applied to the electrostatic electrode 1111b may be decreased in a multi-step manner.

Additionally, as illustrated in FIG. 14, the voltage level of the AC voltage applied to the electrostatic electrode 1111b may be set to zero before stopping the generation of the plasma illustrated in step S305.

According to the processes illustrated in FIGS. 12 to 14, in step S203, the third frequency that is greater than the frequency (the second frequency) of the AC voltage applied to the electrostatic electrode 1111b in the substrate processing (S301) is applied. With this, the residual attraction between the edge ring 112A and the electrostatic chuck 1111 due to the polarization of the water molecules 600 can be suppressed.

Therefore, the substrate dechuck sequence described above includes the following steps (g) to (j):
(g) a step of changing the first to the Nth AC voltages respectively applied to the first to the Nth chuck electrodes 1111b1 to 1111b3 to the third frequency that is greater than the second frequency while maintaining the first voltage level;
(h) a step of generating the third plasma in the plasma processing chamber;
(i) a step of starting decreasing the voltage level of the first to the Nth AC voltages respectively applied to the first to the Nth chuck electrodes 1111b1 to 1111b3; and
(j) a step of stopping the generation of the third plasma.

In one embodiment, step (j) is performed after the first to the Nth AC voltages respectively applied to the first to the Nth chuck electrodes 1111b1 to 1111b3 decrease to the zero voltage level. In one embodiment, step (j) is performed before the first to Nth AC voltages respectively applied to the first to Nth chuck electrodes 1111b1 to 1111b3 decrease to the zero voltage level.

Next, an example of the electrostatic attraction of the edge ring 112A by the electrostatic electrode 1111c of the electrostatic chuck 1111 illustrated in FIG. 3 will be described with reference to FIGS. 15 to 20.

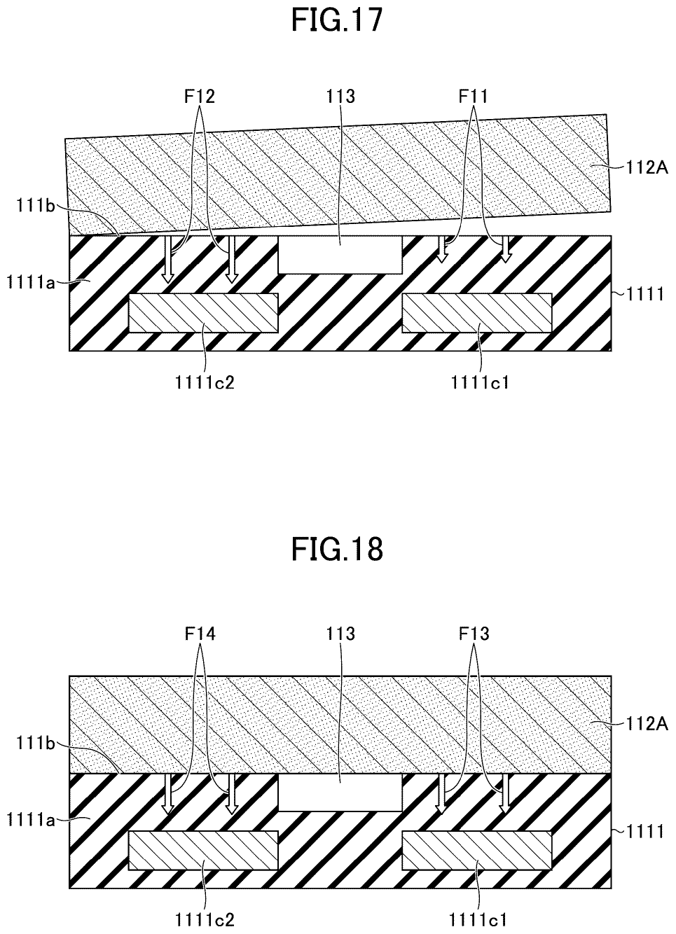

FIG. 15 is an example of a cross-sectional view of the electrostatic chuck 1111 and the edge ring 112A according to one embodiment. Here, an example of the electrostatic chuck 1111 having the electrostatic electrode 1111c illustrated in FIG. 3 will be described. FIG. 15 is an example of the cross-sectional view of the electrostatic chuck 1111 and the edge ring 112A cut at A-A (see FIG. 3). Additionally, in FIG. 15 (and FIGS. 17 to 26, which will be described later), the left side corresponds to the center side of the electrostatic chuck 1111, and the right side corresponds to the outer peripheral side of the electrostatic chuck 1111.

The diffusion groove 113 is provided in the ring support surface (the annular region 111b) of the electrostatic chuck 1111 supporting the edge ring 112A. The diffusion groove 113 diffuses a heat transfer gas into a gap between the edge ring 112A and the ring support surface. Additionally, the diffusion groove 113 is a groove for diffusing the heat transfer gas (which is also referred to as a backside gas) supplied from the heat transfer gas supply through the supply port in the circumferential direction and the radial direction of the ring support surface. The diffusion groove 113 is an annular groove concentrically with the center of the electrostatic chuck 1111. Here, although the illustration is omitted, the supply port communicates with the diffusion groove 113.

The electrostatic electrode 1111c includes the first arc portion 301, the second arc portion 302, the third arc portion 303, and the fourth arc portion 304 in order in the radial direction from the outer peripheral side to the center side. The first arc portion 301 and the third arc portion 303 are connected by the first connection 311 (see FIG. 3), and the first arc portion 301 and the third arc portion 303 constitute the first chuck electrode 1111c1. The second arc portion 302 and the fourth arc portion 304 are connected by the second connection 312 (see FIG. 3), and the second arc portion 302 and the fourth arc portion 304 constitute the second chuck electrode 1111c2.

Additionally, the annular region 111b includes a first annular region in which the first arc portion 301 is arranged from the outer peripheral side, a second annular region in which the second arc portion 302 is arranged, a third annular region in which the third arc portion 303 is arranged, and a fourth annular region in which the fourth arc portion 304 is arranged. The first connection 311 is connected from the first arc portion 301 of the first annular region to the third arc portion 303 of the third annular region through the second annular region. The second arc portion 302 of the second annular region includes a notch, and the first connection 311 is arranged in the notch. The second connection 312 is connected from the second arc portion 302 of the second annular region to the fourth arc portion 304 of the fourth annular region through the third annular region. The third arc portion 303 of the third annular region includes a notch, and the second connection 312 is arranged in the notch.

FIG. 16 is a graph indicating an example of the AC voltage applied to the electrostatic electrode 1111c. In FIG. 16, an example of the AC voltage applied to the first chuck electrode 1111c1 is illustrated by a solid line graph, and an example of the AC voltage applied to the second chuck electrode 1111c2 is illustrated by a dashed line graph. Here, an AC voltage having an amplitude V_{AC} is applied to the first chuck electrode 1111c1. Additionally, an AC voltage having the amplitude V_{AC} and a phase different from the phase of the AC voltage applied to the first chuck electrode 1111c1 is applied to the second chuck electrode 1111c2. Additionally, in FIG. 16, a timing T1 is a timing when the voltage applied to the first chuck electrode 1111c1 is different from the voltage applied to the second chuck electrode 1111c2. Additionally, a timing T2 is a timing when the voltage applied to the first chuck electrode 1111c1 is equal to the voltage applied to the second chuck electrode 1111c2.

FIGS. 17 and 18 are examples of a cross-sectional view of the electrostatic chuck 1111 and the edge ring 112A according to another embodiment. Here, an example of the electrostatic chuck 1111 including the electrostatic electrode 1111c illustrated in FIG. 2 is illustrated. Additionally, in FIG. 17, the magnitude of the attraction force at the timing T1 (see FIG. 16) is indicated by the length of the blank arrow. In FIG. 18, the magnitude of the attraction force at the timing T2 (see FIG. 16) is indicated by the length of the blank arrow.

The electrostatic chuck 1111 illustrated in FIG. 2 and FIGS. 17 and 18 includes the first chuck electrode 1111c1 and the second chuck electrode 1111c2 in order in the radial direction from the outer peripheral side to the center side. That is, it has a double structure.

At the timing T1 illustrated in FIG. 16, the voltage applied to the second chuck electrode 1111c2 is greater than the voltage applied to the first chuck electrode 1111c1. Thus, as illustrated in FIG. 17, an attraction force F11 exerted by the first chuck electrode 1111c1 is small, and the attraction force F12 exerted by the second chuck electrode 1111c2 is large. Therefore, a bias in the attraction force may occur in the radial direction of the edge ring 112A, and the outer peripheral side of the edge ring 112A may float. Here, although the illustration is omitted, at the timing when the voltage applied to the first chuck electrode 1111c1 is greater than the voltage applied to the second chuck electrode 1111c2, the attraction force F11 exerted by the first chuck electrode 1111c1 is large, and the attraction force F12 exerted by the second chuck electrode 1111c2 is small. Therefore, a bias in the attraction force may occur in the radial direction of the edge ring 112A, and the inner peripheral side of the edge ring 112A may float.

At the timing T2 illustrated in FIG. 16, the voltage applied to the first chuck electrode 1111c1 is substantially equal to the voltage applied to the second chuck electrode 1111c2. Therefore, as illustrated in FIG. 18, the attraction force F13 exerted by the first chuck electrode 1111c1 is substantially equal to the attraction force F14 exerted by the second chuck electrode 1111c2.

As described above, in the electrostatic chuck 1111 illustrated in FIG. 2 and FIGS. 17 and 18, the attraction stability of the edge ring 112A may decrease. As the attraction stability of the edge ring 112A decreases, the amount of heat transfer gas leaked from the diffusion groove 113 to the plasma processing space 10s may increase. Additionally, as the contact between the edge ring 112A and the body 111 decreases, the heat transfer from the edge ring 112A to the body 111 may decrease.

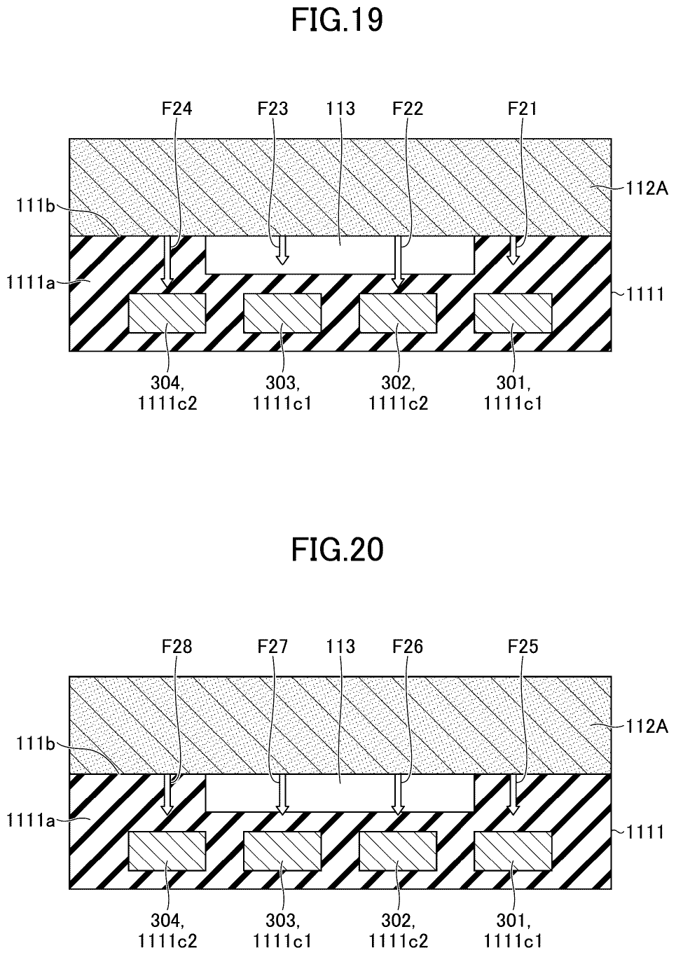

FIGS. 19 and 20 are examples of a cross-sectional view of the electrostatic chuck 1111 and the edge ring 112A according to one embodiment. Here, as in FIG. 15, an example of the electrostatic chuck 1111 including the electrostatic electrode 1111c illustrated in FIG. 3 is illustrated. Additionally, in FIG. 19, the magnitude of the attraction force at the timing T1 (see FIG. 16) is indicated by the length of the blank arrow. In FIG. 20, the magnitude of the attraction force at the timing T2 (see FIG. 16) is indicated by the length of the blank arrow.

The electrostatic chuck 1111 illustrated in FIG. 3 and FIGS. 19 and 20 includes the first arc portion 301 (the first chuck electrode 1111c1), the second arc portion 302 (the second chuck electrode 1111c2), the third arc portion 303 (the first chuck electrode 1111c1), and the fourth arc portion 304 (the second chuck electrode 1111c2) in order in the radial direction from the outer peripheral side to the center side. That is, it has a quadruple structure.

At the timing T1 illustrated in FIG. 16, the voltage applied to the second chuck electrode 1111c2 is greater the voltage applied to the first chuck electrode 1111c1. Thus, as illustrated in FIG. 19, attraction forces F21 and F23 exerted by the first chuck electrode 1111c1 are small, and the attraction forces F22 and F24 exerted by the second chuck electrode 1111c2 are large. However, the first chuck electrode 1111c1 and the second chuck electrode 1111c2 are arranged alternately in the radial direction, so that the bias in the distribution of the attraction force in the radial direction of the edge ring 112A is suppressed. With this, the floating of the edge ring 112A can be suppressed. Here, although the illustration is omitted, the bias in the distribution of the attraction force in the radial direction of the edge ring 112A is similarly suppressed at the timing when the voltage applied to the first chuck electrode 1111c1 is greater than the voltage applied to the second chuck electrode 1111c2. With this, the floating of the edge ring 112A can be suppressed.

At the timing T2 illustrated in FIG. 16, the voltage applied to the first chuck electrode 1111c1 is substantially equal to the voltage applied to the second chuck electrode 1111c2. Thus, as illustrated in FIG. 20, the attraction forces F25 and F27 exerted by the first chuck electrode 1111c1 are substantially equal to the attraction forces F26 and F28 exerted by the second chuck electrode 1111c2.

As described above, in the electrostatic chuck 1111 illustrated in FIG. 3 and FIGS. 15, 19 and 20, the chuck electrodes 1111c1 and 1111c2 have a multi-ring structure. That is, the first chuck electrode 1111c1 includes the first arc portion 301 and the third arc portion 303 having different diameters. The second chuck electrode 1111c2 includes the second arc portion 302 and the fourth arc portion 304 having different diameters. The arc portion of the first chuck electrode 1111c1 and the arc portion of the second chuck electrode 1111c2 are arranged alternately in the radial direction. That is, one chuck electrode includes a plurality of arc portions, another chuck electrode includes a plurality of arc portions, and the arc portion of the one chuck electrode and the arc portion of the other chuck electrode are arranged alternately in the radial direction. With this, the bias in the distribution of the attraction force in the radial direction of the edge ring 112A is suppressed. With this, the floating of the edge ring 112A can be suppressed.

Additionally, the first chuck electrode 1111c1 includes the first connection 311 that connects the first arc portion 301 to the third arc portion 303. The second chuck electrode 1111c2 includes the second connection 312 that connects the second arc portion 302 to the fourth arc portion 304. With this, the voltage can be applied to the plurality of arc portions from a single power supply. Therefore, an increase in the supply line from the power supplies 163 and 164 to the chuck electrodes 1111c1 and 1111c2 can be suppressed.

Here, although the shape of the diffusion groove 113 has been described as an annular shape, it is not limited thereto.

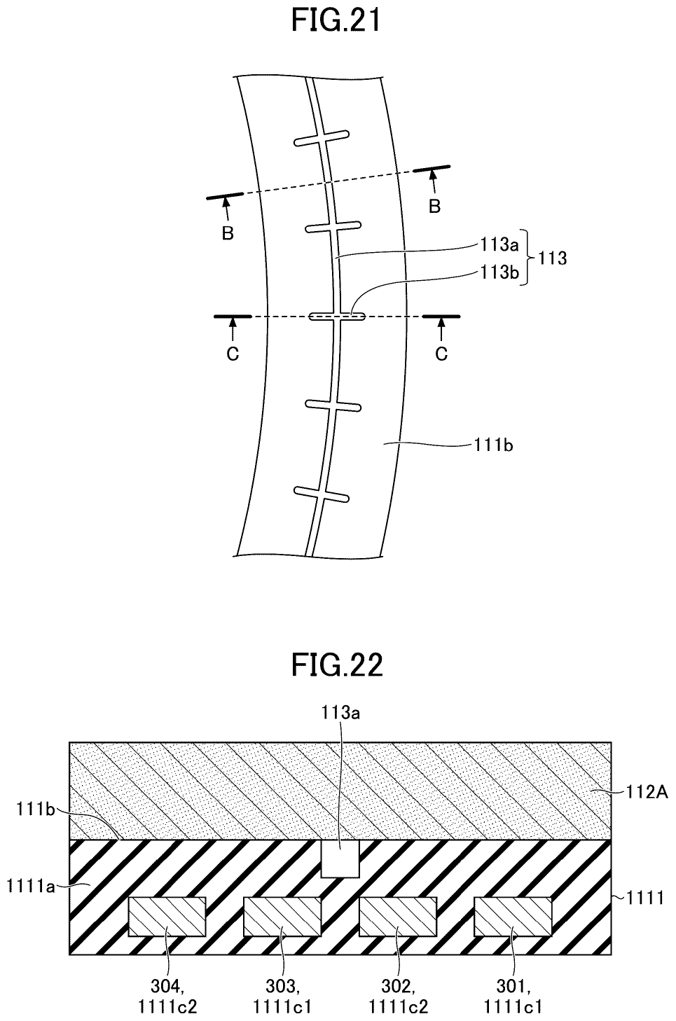

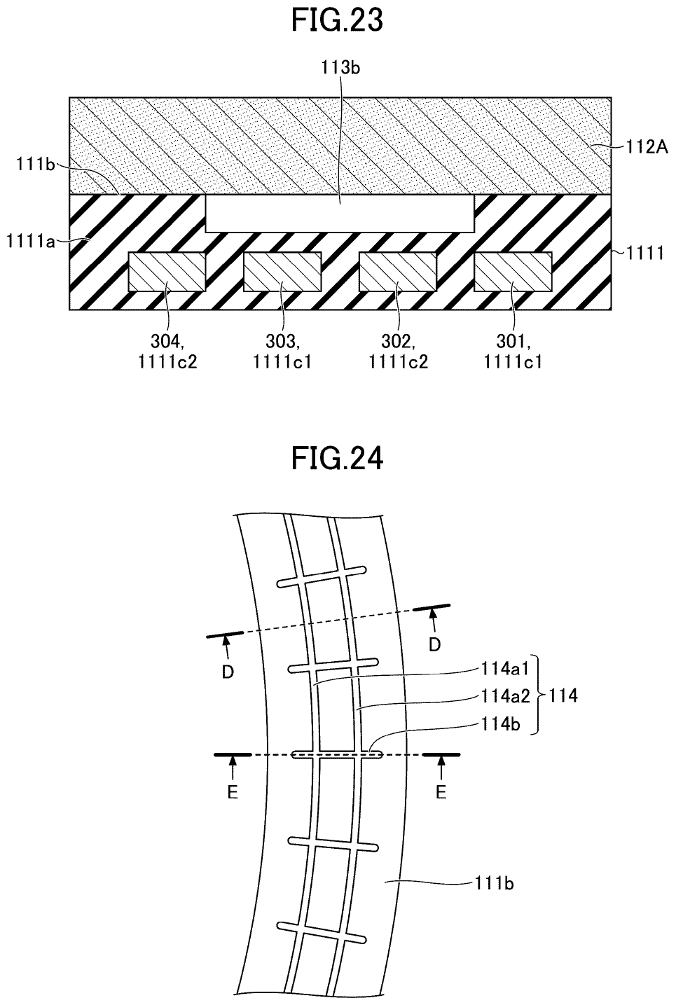

FIG. 21 is an example of a partially enlarged view of the annular region 111b of the electrostatic chuck 1111. Here, the partially enlarged view illustrated in FIG. 21 is a top view of the electrostatic chuck 1111. FIG. 22 is an example of a cross-sectional view of the electrostatic chuck 1111 and the edge ring 112A cut at B-B. FIG. 23 is an example of a cross-sectional view of the electrostatic chuck 1111 and the edge ring 112A cut at C-C.

The diffusion groove 113 is provided in the ring support surface (the annular region 111b) of the electrostatic chuck 1111 supporting the edge ring 112A. The diffusion groove 113 diffuses the heat transfer gas into a gap between the edge ring 112A and the ring support surface. Additionally, the diffusion groove 113 is a groove for diffusing the heat transfer gas (which is also referred to as the backside gas) supplied from a supply port (not illustrated) in the circumferential direction and the radial direction of the ring support surface.

The diffusion groove 113 includes an annular groove 113a and a plurality of radial grooves 113b.

The annular groove 113a is provided in the ring support surface (the annular region 111b) of the electrostatic chuck 1111 and is an annular groove concentric with the center of the electrostatic chuck 1111. Here, although not illustrated, the supply port (not illustrated) communicates with the annular groove 113a.

The radial groove 113b is provided in the ring support surface (the annular region 111b) of the electrostatic chuck 1111, communicates with the annular groove 113a, and is a groove extending in the radial direction of the electrostatic chuck 1111 from the annular groove 113a. Additionally, as illustrated in FIG. 21, the radial groove 113b is formed as a groove extending from the annular groove 113a to the outer side and the inner side in the radial direction. That is, one end of the radial groove 113b is provided on the inner side of the annular groove 113a in the radial direction. Additionally, the other end of the radial groove 113b is provided on the outer side of the annular groove 113a in the radial direction.

Here, the radial groove 113b is not limited to the one illustrated in FIG. 21, and may be formed as a groove extending from the annular groove 113a to the outer side in the radial direction, the inner side in the radial direction, or both. Additionally, the radial groove 113b may be formed as a groove extending from the annular groove 113a to the outer peripheral side of the electrostatic chuck 1111, the inner peripheral side of the electrostatic chuck 1111, or both.

As described above, the heat transfer gas supplied from the supply port (not illustrated) is diffused in the circumferential direction of the ring support surface by the annular groove 113a. Further, the heat transfer gas is diffused in the radial direction of the ring support surface by the radial groove 113b. That is, the heat transfer gas is diffused over the entirety of the ring support surface.

Additionally, when the ring support surface is viewed in plan view, the annular groove 113a is at a position that does not overlap each of the arc portions 301 to 304 of the electrostatic electrode 1111c. In the example illustrated in FIG. 22, the annular groove 113a is provided on the outer peripheral side of the third arc portion 303 and on the inner peripheral side of the second arc portion 302. That is, in the radial direction, the inner peripheral side surface of the annular groove 113a is provided aligned with or outside the outer peripheral side end surface of the third arc portion 303. Additionally, in the radial direction, the outer peripheral side surface of the annular groove 113a is provided aligned with or inside the inner peripheral side end surface of the second arc portion 302.

Here, in FIG. 22, the annular groove 113a has been described as being provided at a position that does not overlap each of the arc portions 301 to 304 of the electrostatic electrode 1111c, but the embodiment is not limited thereto. It may have a configuration in which some of them overlap. For example, when the inner peripheral side of the annular groove 113a overlaps the third arc portion 303, it is preferable that the percentage of the area where the annular groove 113a and the third arc portion 303 overlap with respect to the area of the third arc portion 303 is 17% or less. Similarly, when the outer peripheral side of the annular groove 113a overlaps the second arc portion 302, it is preferable that the percentage of the area where the annular groove 113a overlaps the second arc portion 302 with respect to the area of the second arc portion 302 is 36% or less.

Additionally, when the ring support surface is viewed in plan view, the radial groove 113b is at a position where the radial groove 113b partially overlaps the arc portions 301 to 304 of the electrostatic electrode 1111c. In the example illustrated in FIG. 23, the radial groove 113b is provided so as to overlap the second arc portion 302 and the third arc portion 303.

Next, the attraction force for electrostatically attracting the edge ring 112A will be described.

Here, an attraction force F can be expressed by the following equation (2). Here, C is the equivalent capacity, V is the voltage, and d is the distance between the electrode plates (the distance between the electrostatic electrode 1111c and the edge ring 112A).

F=CV²/2d (2)

As illustrated in Equation (2), even when the voltage V applied to each of the arc portions 301 to 304 of the electrostatic electrode 1111c is identical and the distance d between the electrode plates is identical, the attraction force F will be different if the equivalent capacitance C is different.

The annular groove 113a of the diffusion groove 113 is provided so as not to overlap the electrostatic electrode 1111c. That is, the equivalent capacitance C in the first arc portion 301 to the fourth arc portion 304 is approximately identical. With this, the attraction force at the first arc portion 301, the attraction force at the second arc portion 302, the attraction force at the third arc portion 303, and the attraction force at the fourth arc portion 304 can be substantially identical. With this, the in-plane uniformity of the attraction force exerted by the electrostatic chuck 1111 is improved. Additionally, the in-plane uniformity of the attraction force is improved, so that the temperature control of the edge ring 112A can be stabilized. Additionally, the in-plane uniformity of the attraction force is improved, so that the micro-vibration of the edge ring 112A can be suppressed.

As described above, according to the electrostatic chuck 1111 including the diffusion groove 113 of the present embodiment, the positional dependence of the attraction force is relaxed, and the in-plane uniformity of the attraction force is improved. Additionally, the in-plane uniformity of the attraction force is improved, so that the uniformity of cooling of the edge ring 112A is also improved.

Here, it is preferable that the width of the annular groove 113a is less than the interval between the third arc portion 303 and the second arc portion 302. In other words, it is preferable that the width falls between the outer diameter of the third arc portion 303 and the inner diameter of the second arc portion 302.

It is preferable that the length (the width in the longitudinal direction) of the radial groove 113b falls between the outer diameter of the fourth arc portion 304 and the inner diameter of the first arc portion 301. Additionally, the overlap amount between each of the arc portions 302 and 303 and the diffusion groove 113 is determined based on the width of the annular groove 113a, the length (the width in the longitudinal direction) of the radial groove 113b, the number of the radial grooves 113b, and the width (the width in the transverse direction) of the radial groove 113b. The number of the radial grooves 113b and the width (the width in the transverse direction) of the radial grooves 113b are preferably set such that, when the length (the width in the long direction) of the radial grooves 113b and the width of the annular grooves 113a are determined, the overlap amount between the third arc portion 303 and the diffusion groove 113 is 24.5% or less with respect to the electrode area of the third arc portion 303, and the overlap amount between the second arc portion 302 and the diffusion groove 113 is 45% or less with respect to the electrode area of the second arc portion 302.

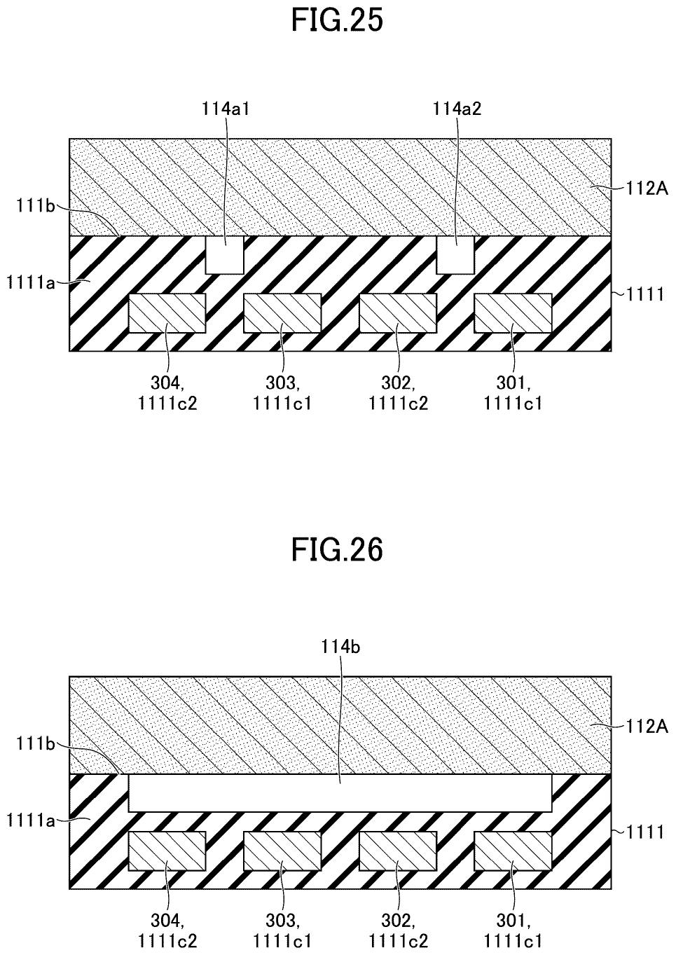

FIG. 24 is an example of a partially enlarged view of the annular region 111b of the electrostatic chuck 1111. Here, the partially enlarged view illustrated in FIG. 24 is a top view of the electrostatic chuck 1111. FIG. 25 is an example of a cross-sectional view of the electrostatic chuck 1111 and the edge ring 112A cut at D-D. FIG. 26 is an example of a cross-sectional view of the electrostatic chuck 1111 and the edge ring 112A cut at E-E.

A diffusion groove 114 is provided in the ring support surface (the annular region 111b) of the electrostatic chuck 1111 supporting the edge ring 112A. The diffusion groove 114 is a groove for diffusing the heat transfer gas (which is also referred to as the backside gas) supplied from the supply port (not illustrated) in the circumferential direction and the radial direction of the ring support surface.

The diffusion groove 114 includes an annular groove 114a1, an annular groove 114a2, and a plurality of radial grooves 114b.

The annular grooves 114a1 and 114a2 are provided in the ring support surface (the annular region 111b) of the electrostatic chuck 1111 and is an annular groove concentrically with the center of the electrostatic chuck 1111. Here, although not illustrated, the supply port (not illustrated) communicates with one of the annular groove 114a1 or the annular groove 114a2.

The radial groove 114b is provided in the ring support surface (the annular region 111b) of the electrostatic chuck 1111, communicates with the annular grooves 114a1 and 114a2, and is a groove extending in the radial direction of the electrostatic chuck 1111 from the annular grooves 114a1 and 114a2. That is, the radial groove 114b communicates with the annular groove 114a1 and the annular groove 114a2. Additionally, as illustrated in FIG. 24, the radial groove 114b is formed as a groove extending from the annular grooves 114a1 and 114a2 to the outer side and the inner side in the radial direction. That is, one end of the radial groove 114b is provided inside the annular groove 114a1, which is arranged on the innermost side among the plurality of annular grooves 114a1 and 114a2, in the radial direction. Additionally, the other end of the radial groove 114b is provided on the outer side of the annular groove 114a2, which is arranged on the outermost side among the plurality of annular grooves 114a1 and 114a2, in the radial direction.

Here, the radial groove 114b is not limited to the one illustrated in FIG. 24, and may be formed as a groove extending from the annular grooves 114a1 and 114a2 to the outer side, the inner side, or both. Additionally, the radial groove 114b may be formed as a groove extending from the annular grooves 114a1 and 114a2 to the outer peripheral side of the electrostatic chuck 1111, the inner peripheral side of the electrostatic chuck 1111, or both. Additionally, the radial groove 114b has been described as including the groove extending from the annular groove 114a1 to the inner side in the radial direction, the groove communicating with the annular groove 114a2 from the annular groove 114a1, and the groove extending from the annular groove 114a2 to the outer side in the radial direction that are arranged in a straight line, but it is not limited thereto, and may be divided.

As described above, the heat transfer gas supplied from the supply port (not illustrated) is diffused in the circumferential direction of the ring support surface by the annular grooves 114a1 and 114a2. Further, the heat transfer gas is diffused in the radial direction of the ring support surface by the radial groove 114b. That is, the heat transfer gas is diffused over the entirety of the ring support surface.

Additionally, when the ring support surface is viewed in plan view, the annular grooves 114a1 and 114a2 are provided at positions which do not overlap each of the arc portions 301 to 304 of the electrostatic electrode 1111c. In the example illustrated in FIG. 25, the annular groove 114a1 is provided on the outer peripheral side of the fourth arc portion 304 and on the inner peripheral side of the third arc portion 303. That is, in the radial direction, the inner peripheral side surface of the annular groove 114a1 is provided aligned with or outside the outer peripheral side end surface of the fourth arc portion 304. Additionally, in the radial direction, the outer peripheral side surface of the annular groove 114a1 is provided aligned with or inside the inner peripheral side end surface of the third arc portion 303. Additionally, the annular groove 114a2 is provided on the outer peripheral side of the second arc portion 302 and on the inner peripheral side of the first arc portion 301. That is, in the radial direction, the inner peripheral side surface of the annular groove 114a2 is provided aligned with or outside the outer peripheral side end surface of the second arc portion 302. Additionally, in the radial direction, the outer peripheral side surface of the annular groove 114a2 is provided aligned with or inside the inner peripheral side end surface of the first arc portion 301.

Here, in FIG. 25, the annular grooves 114a1 and 114a2 and each of the arc portions 301 to 304 of the electrostatic electrode 1111c have been described as being provided at positions that do not overlap, but the embodiment is not limited thereto. It may have a configuration in which some of them overlap.

Additionally, when the ring support surface is viewed in plan view, the radial groove 114b is at a position where the radial groove 114b partially overlaps the arc portions 301 to 304 of the electrostatic electrode 1111c. In the example illustrated in FIG. 26, the radial groove 114b is provided so as to overlap with the arc portions 301 to 304.

Additionally, the number of annular grooves of the diffusion groove is not limited thereto, but may be three or greater. For example, the diffusion groove may be configured to include an annular groove provided between the fourth arc portion 304 and the third arc portion 303, an annular groove provided between the third arc portion 303 and the second arc portion 302, and an annular groove provided between the second arc portion 302 and the first arc portion 301. Additionally, the diffusion groove may include an annular groove provided on the inner peripheral side of the fourth arc portion 304. Additionally, the diffusion groove may include an annular groove provided on the outer peripheral side of the first arc portion 301. The radial groove is provided so as to communicate these annular electrostatic electrodes.

Additionally, the electrostatic electrode 1111c has been described as being provided in a plurality of annular shapes, but are not limited thereto. The electrostatic electrode 1111c may be formed by spirally winding two electrodes. In this case, the diffusion groove may include a spiral groove spirally provided between the two electrodes and a plurality of radial grooves when viewed in plan view.

Additionally, the diffusion grooves 113 and 114 provided on the ring support surface (the annular region 111b) supporting the edge ring 112A have been described as an example, but the embodiment is not limited thereto. The same may be applied to the diffusion groove in the substrate support surface (the annular region 111b) supporting the substrate W. That is, the diffusion groove provided in the substrate support surface (the annular region 111b) may include one or more annular grooves provided so as not to overlap the electrostatic electrode 1111b when viewed in plan view, and a plurality of radial grooves communicating with the one or more annular grooves.

As described above, the electrostatic chuck 1111 illustrated in FIG. 3 has been described as an example, but the electrostatic chuck 1111 illustrated in FIG. 4 can similarly suppress the bias in the distribution of the attraction force in the radial direction of the edge ring 112A. Additionally, the floating of the edge ring 112A can be suppressed. Additionally, the increase of the supply line from the power supplies 163 and 164 to the chuck electrodes 1111c1 and 1111c2 can be suppressed.

Additionally, although the description has been provided using the 2-pole electrostatic electrode 1111c as an example, the embodiment is not limited thereto and may be applied to the 3-pole electrostatic electrode 1111c.

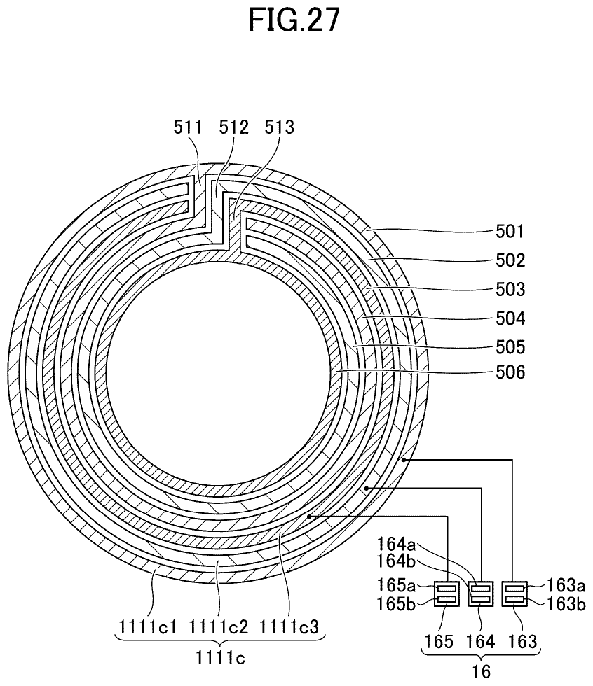

FIG. 27 is a plan view illustrating yet another example of the arrangement of the electrostatic electrode 1111c of the electrostatic chuck 1111. As illustrated in FIG. 27, the 3-pole electrostatic electrode 1111c may be used.

The electrostatic electrode 1111c includes a first arc portion 501, a second arc portion 502, a third arc portion 503, a fourth arc portion 504, a fifth arc portion 505, and a sixth arc portion 506 in order in the radial direction from the outer peripheral side to the center side. Additionally, the electrostatic electrode 1111c includes a first connection 511 connecting the first arc portion 501 to the fourth arc portion 504, a second connection 512 connecting the second arc portion 502 to the fifth arc portion 505, and a third connection 513 connecting the third arc portion 503 to the sixth arc portion 506.

The first chuck electrode 1111c1 includes the first arc portion 501, the first connection 511, and the fourth arc portion 504. The second chuck electrode 1111c2 includes the second arc portion 502, the second connection 512, and the fifth arc portion 505. The third chuck electrode 1111c3 includes the third arc portion 503, the third connection 513, and the sixth arc portion 506.

The chuck power supply 16 includes the first power supply 163, the second power supply 164, and a third power supply 165. The first power supply 163 applies the AC voltage (the first AC voltage) to the first chuck electrode 1111c1. The second power supply 164 applies the AC voltage (the second AC voltage) to the second chuck electrode 1111c2. The third power supply 165 applies the AC voltage (the third AC voltage) to the third chuck electrode 1111c3. Here, the power supply 163 includes the AC power supply 163a and the DC power supply 163b. The AC power supply 163a generates the AC voltage and applies it to the first chuck electrode 1111c1. The DC power supply 163b generates the DC voltage and superimposes it on the AC voltage applied to the first chuck electrode 1111c1. Here, the power supply 163 may be configured to include only one of the AC power supply 163a or the DC power supply 163b. Similarly, the power supply 164 includes the AC power supply 164a and the DC power supply 164b. Additionally, the third power supply 165 includes an AC power supply 165a and a DC power supply 165b. Further, the AC voltage of the first power supply 163, the AC voltage of the second power supply 164, and the AC voltage of the third power supply 165 are phase-shifted with each other.

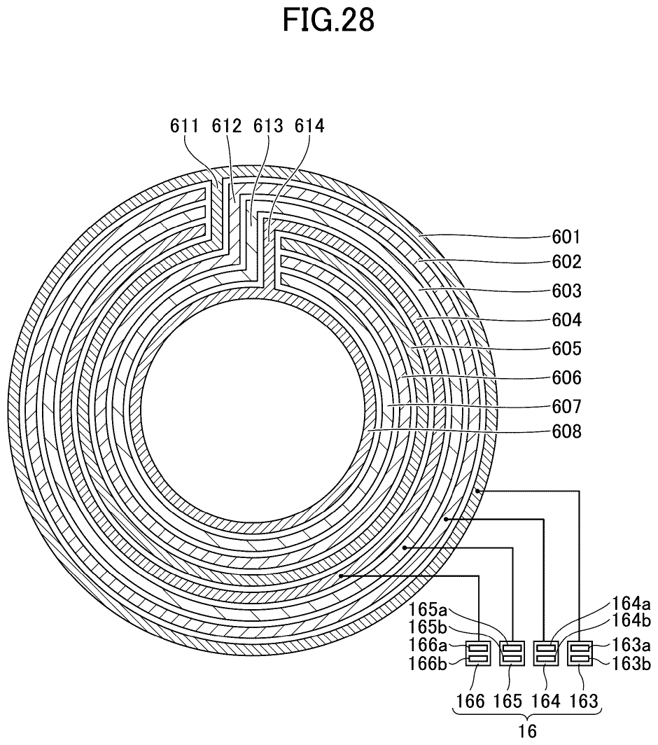

FIG. 28 is a plan view illustrating yet another example of the arrangement of the electrostatic electrode 1111c of the electrostatic chuck 1111. As illustrated in FIG. 28, the four-pole electrostatic electrode 1111c may be used.

The electrostatic electrode 1111c includes a first arc portion 601, a second arc portion 602, a third arc portion 603, a fourth arc portion 604, a fifth arc portion 605, a sixth arc portion 606, a seventh arc portion 607, and an eighth arc portion 608 in order in the radial direction from the outer peripheral side to the center side. Additionally, the electrostatic electrode 1111c includes a first connection 611 connecting the first arc portion 601 to the fifth arc portion 605, a second connection 612 connecting the second arc portion 602 to the sixth arc portion 606, a third connection 613 connecting the third arc portion 603 to the seventh arc portion 607, and a fourth connection 614 connecting the fourth arc portion 604 to the eighth arc portion 608.

The first chuck electrode 1111c1 includes the first arc portion 601, the first connection 611, and the fifth arc portion 605. The second chuck electrode 1111c2 includes the second arc portion 602, the second connection 612, and the sixth arc portion 606. The third chuck electrode 1111c3 includes the third arc portion 603, the third connection 613, and the seventh arc portion 607. The fourth chuck electrode 1111c4 includes the fourth arc portion 604, the fourth connection 614, and the eighth arc portion 608.

The chuck power supply 16 includes the first power supply 163, the second power supply 164, the third power supply 165, and a fourth power supply 166. The first power supply 163 applies the AC voltage (the first AC voltage) to the first chuck electrode 1111c1. The second power supply 164 applies the AC voltage (the second AC voltage) to the second chuck electrode 1111c2. The third power supply 165 applies the AC voltage (the third AC voltage) to the third chuck electrode 1111c3. The fourth power supply 166 applies an AC voltage (a fourth AC voltage) to the fourth chuck electrode 1111c4. Here, the power supply 163 includes the AC power supply 163a and the DC power supply 163b. The AC power supply 163a generates the AC voltage and applies it to the first chuck electrode 1111c1. The DC power supply 163b generates the DC voltage and superimposes it on the AC voltage applied to the first chuck electrode 1111c1. Here, the power supply 163 may be configured to include only one of the AC power supply 163a or the DC power supply 163b. Similarly, the power supply 164 includes the AC power supply 164a and the DC power supply 164b. Additionally, the third power supply 165 includes the AC power supply 165a and the DC power supply 165b. Additionally, the fourth power supply 166 includes an AC power supply 166a and a DC power supply 166b. Further, the AC voltage of the first power supply 163, the AC voltage of the second power supply 164, the AC voltage of the third power supply 165, and the AC voltage of the fourth power supply 166 are phase-shifted with each other.

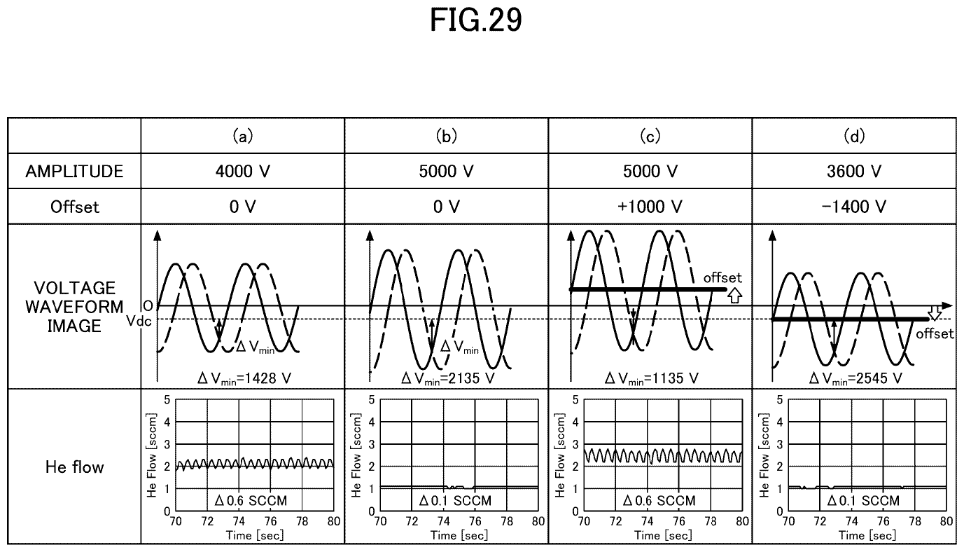

Next, a relationship between the voltage applied to the electrostatic electrode 1111c (the chuck electrodes 1111c1 and 1111c2) and the attraction force will be further described with reference to FIG. 29. FIG. 29 is a graph indicating a relationship between the voltage and a flow of the heat transfer gas.

In FIG. 29, the “amplitude” indicates the amplitude of the AC voltage applied to the electrostatic electrode 1111c. The “offset” indicates the offset voltage of the AC voltage applied to the electrostatic electrode 1111c. In the “voltage waveform image”, the horizontal axis indicates the time, and the vertical axis indicates the voltage applied to the electrostatic electrode 1111c (the chuck electrodes 1111c1 and 1111c2). Additionally, the AC voltage applied to the first chuck electrode 1111c1 is illustrated by a solid line, and the AC voltage applied to the second chuck electrode 1111c2 is illustrated by a dashed line. Additionally, the self-bias voltage Vdc (−1400 V in the example illustrated in FIG. 29) is illustrated by a dotted line. ΔVₘᵢₙ is the minimum voltage difference between the voltage applied to the electrostatic electrode 1111c and the self-bias voltage Vdc. In (c) and (d), the offset voltage (the average voltage for one cycle, i.e., the center of the amplitude of the AC voltage) is schematically illustrated by a thick solid line. In “He flow”, the horizontal axis indicates the time, and the vertical axis indicates the flow rate of He gas (the heat transfer gas) supplied to the diffusion groove 113.

For example, the power supply 161 includes the AC power supply 161a and the DC power supply 161b. The AC power supply 161a generates the AC voltage and applies it to the first chuck electrode 1111c1. The DC power supply 161b generates the offset voltage and superimposes it on the AC voltage applied to the first chuck electrode 1111c1.

(a) indicates a case where the voltage applied to the electrostatic electrode 1111c is set to an amplitude of 4000 V and an offset voltage of 0 V. The minimum voltage difference ΔVₘᵢₙ is 1428 V. In this case, the flow rate of He gas fluctuates. The fluctuation width A of the flow rate of He gas is 0.6 sccm. That is, it indicates that the attraction force fluctuates.

(b) indicates a case where the voltage applied to the electrostatic electrode 1111c is set to an amplitude of 5000 V and an offset voltage of 0 V. The minimum voltage difference ΔVₘᵢₙ is 2135 V. That is, by increasing the amplitude of the applied voltage, the minimum voltage difference ΔVₘᵢₙ is increased in comparison with (a). In this case, the fluctuation of the flow rate of He gas is suppressed. The fluctuation width Δ of the flow rate of He gas is 0.1 sccm. That is, by increasing the amplitude of the applied voltage, the fluctuation of the attraction force is suppressed, and the floating of the edge ring 112A is prevented.

(c) indicates a case where the voltage applied to the electrostatic electrode 1111c is set to an amplitude of 5000 V, and the DC voltage is superimposed (offset) in the opposite direction of the self-bias voltage Vdc. Here, the voltage is offset with +1000 V. The minimum voltage difference ΔVₘᵢₙ is 1135 V. That is, by being offset with the voltage in the opposite direction to the self-bias voltage Vdc, the minimum voltage difference ΔVₘᵢₙ becomes less than those in (a) and (b). In this case, the flow rate of He gas fluctuates. The fluctuation width A of the flow rate of He gas is 0.6 sccm. That is, it indicates that the attraction force fluctuates.

(d) indicates a case where the voltage applied to the electrostatic electrode 1111c is set to an amplitude of 3600 V and the DC voltage is superimposed (offset) in the same direction as the self-bias voltage Vdc. Here, the voltage is offset with −1400 V. The minimum voltage difference ΔVₘᵢₙ is 2545 V. That is, by being offset with the DC voltage in the same direction as the self-bias voltage Vdc, the minimum voltage difference ΔVₘᵢₙ becomes greater than those in (a) to (c). In this case, the fluctuation of the flow rate of He gas is suppressed. The fluctuation width Δ of the flow rate of He gas is 0.1 sccm. That is, with respect to the voltage applied to the electrostatic electrode 1111c, by being offset with the DC voltage in the same direction as the self-bias voltage Vdc, the minimum voltage difference ΔVₘᵢₙ can be increased, the fluctuation of the attraction force can be suppressed, and the floating of the edge ring 112A can be prevented.

As described above, by offsetting the voltage applied to the electrostatic electrode 1111c with the voltage in the same direction as the self-bias voltage Vdc, the stability of attraction can be improved while suppressing the amplitude.

Additionally, by suppressing the amplitude of the voltage applied to the electrostatic electrode 1111c, power can be saved.

Additionally, the offset amount of the voltage applied to the electrostatic electrode 1111c is a DC voltage (a negative DC voltage) in the same direction as the self-bias voltage Vdc (−1400 V in the example illustrated in FIG. 29). Additionally, the offset amount of the voltage applied to the electrostatic electrode 1111c is preferably set to the self-bias voltage Vdc (see FIG. 29 (d)). With this, the minimum voltage difference ΔVₘᵢₙ can be increased.

Here, the offset amount of the voltage applied to the electrostatic electrode 1111c is not limited to the self-bias voltage Vdc. The offset amount of the voltage applied to the electrostatic electrode 1111c is preferably within the range of 50% to 150% of the self-bias voltage Vdc.

That is, the controller 2 controls the chuck power supply 16 to control the DC voltage (offset amount) superimposed on the AC voltage applied to the electrostatic electrode 1111c (the chuck electrodes 1111c1 and 1111c2). With this, the stability of attraction can be improved while suppressing the amplitude.

Additionally, the voltage applied to the electrostatic electrode 1111c for electrostatically attracting the edge ring 112A has been described, but the embodiment not limited thereto. The AC voltage applied to the electrostatic electrode 1111b for electrostatically attracting the substrate W may be offset with a DC voltage (a negative DC voltage) in the same direction as the self-bias voltage Vdc.

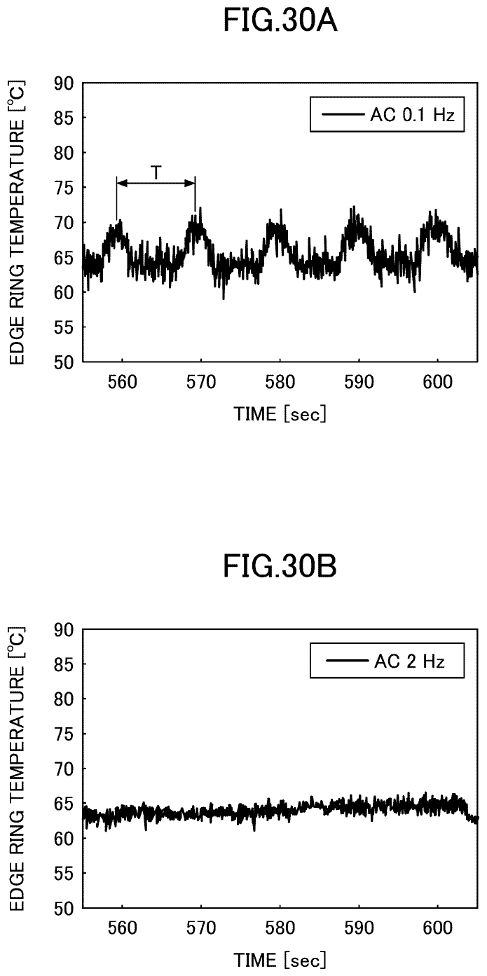

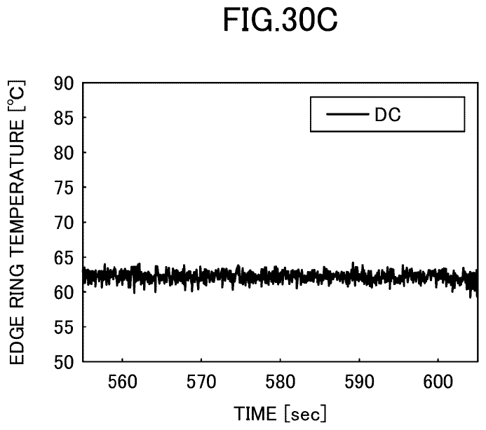

Next, a relationship between the voltage applied to the electrostatic electrode 1111c (the chuck electrodes 1111c1 and 1111c2) and the temperature of the edge ring 112A will be further described with reference to FIGS. 30A to 30C. FIGS. 30A to 30C are graphs indicating examples of the temperature change of the edge ring 112A. The horizontal axis indicates the time, and the vertical axis indicates the temperature change of the edge ring 112A. Additionally, FIG. 30A indicates a case where the frequency of the AC voltage applied to the electrostatic electrode 1111c is 0.1 Hz. FIG. 30B indicates a case where the frequency of the AC voltage applied to the electrostatic electrode 1111c is 2 Hz. FIG. 30C indicates a case where the DC voltage is applied to the electrostatic electrode 1111c.

In FIGS. 30B and 30C, the temperature of the edge ring 112A can be substantially constant.

With respect to the above, in FIG. 30A, the temperature of the edge ring 112A can be fluctuated in a period T (10 sec) corresponding to the frequency of the AC voltage (0.1 Hz). As described above, by controlling the frequency of the AC voltage applied to the electrostatic electrode 1111c, the temperature of the edge ring 112A can be controlled while retaining the attraction of the edge ring 112A.

That is, the controller 2 controls the chuck power supply 16 to control the frequency of the AC voltage applied to the electrostatic electrode 1111c (the chuck electrodes 1111c1 and 1111c2). With this, the temperature of the edge ring 112A can be controlled.

Additionally, the voltage applied to the electrostatic electrode 1111c for electrostatically attracting the edge ring 112A has been described, but the embodiment is not limited thereto. The temperature of the substrate W may be controlled by controlling the frequency of the AC voltage applied to the electrostatic electrode 1111b for electrostatically attracting the substrate W.

Next, the attraction force of the substrate W will be described. Here, in the following description, an example of the attraction of the substrate W will be described, but the embodiment is not limited thereto. The same applies to the attraction of the edge ring 112A of the ring assembly 112, and duplicated descriptions will be omitted.

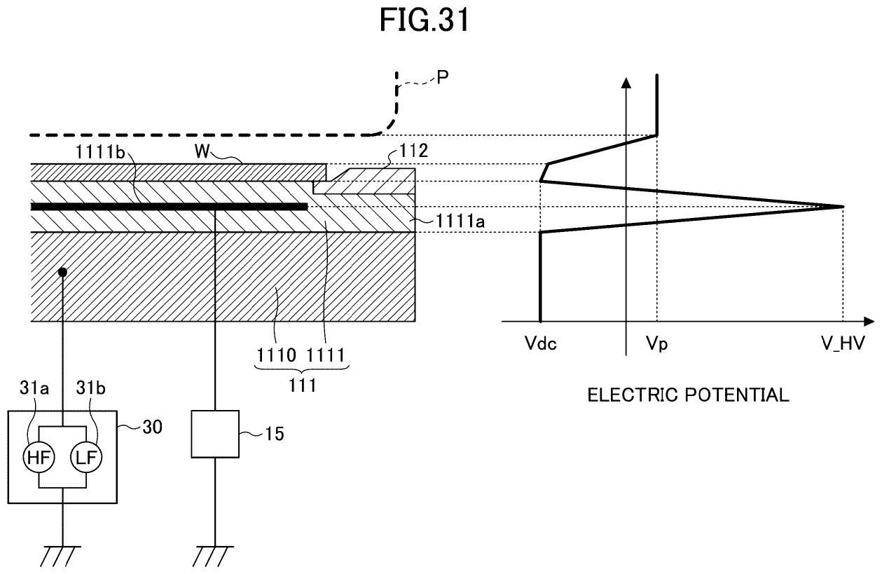

FIG. 31 is an example of a partially enlarged cross-sectional view of the substrate support 11 and a graph indicating a relationship with the electric potential.

To the conductive member of the base 1110 that functions as the lower electrode, a source RF signal (hereinafter, which is also referred to as HF) is supplied from the first RF generator 31a and a RF bias signal (hereinafter, which is also referred to as LF) is supplied from the second RF generator 31b. Additionally, in the examples of FIGS. 31 to 33, it is assumed that a DC voltage V_HV is applied from the chuck power supply 15 to the electrostatic electrode 1111b.

As illustrated in the graph of FIG. 31, the electric potential of the base 1110 becomes the self-bias voltage Vdc. The electric potential rises from the upper surface of the base 1110 (the lower surface of the electrostatic chuck 1111) toward the electrostatic electrode 1111b, and the electric potential of the electrostatic electrode 1111b becomes the voltage V_HV applied from the chuck power supply 15. The electric potential falls from the electrostatic electrode 1111b toward the back surface of the substrate W (the substrate support surface of the electrostatic chuck 1111), and the electric potential at the back surface of the substrate W (the substrate support surface of the electrostatic chuck 1111) becomes the self-bias voltage Vdc. The electric potential rises from the surface of the substrate W toward the sheath of the plasma P, and the electric potential of the plasma P becomes a voltage Vp.

As described above, the electric potential difference between the back surface of the substrate W and the electrostatic electrode 1111b is defined as (V_HV−Vdc). Additionally, the electrostatic attraction force (the wafer attraction force) of the substrate W is proportional to (V_HV−Vdc)².

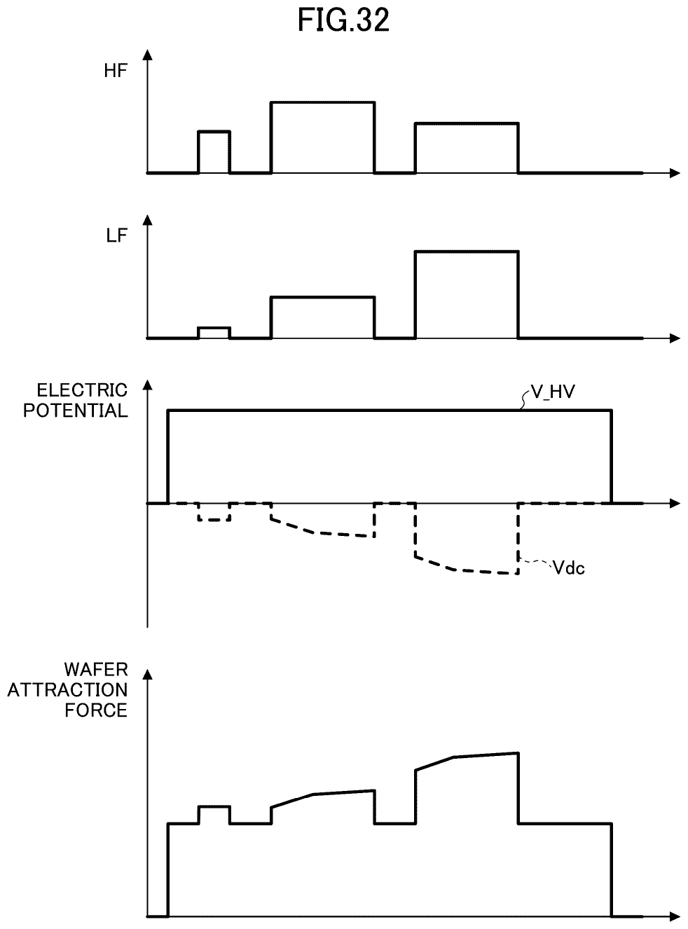

FIG. 32 is a graph indicating a wafer attraction force in an example of plasma processing. Here, HF indicates the output of the source RF signal. LF indicates the output of the RF bias signal. As the electric potential, the voltage V_HV applied from the chuck power supply 15 and the self-bias voltage Vdc are indicated. The wafer attraction force indicates the electrostatic attraction force of the substrate W. The horizontal axis indicates the time. Here, the substrate W is subjected to plasma processing by using HF and LF illustrated in FIG. 32. At this time, the self-bias voltage Vdc illustrated by the dashed line is generated. In the plasma processing, the self-bias voltage Vdc changes in accordance with the plasma processing conditions (HF and LF).

Here, the controller 2 controls the voltage V_HV (indicated by the solid line) applied from the chuck power supply 15 to the electrostatic electrode 1111b at a constant value. In this case, as the self-bias voltage Vdc changes, the wafer attraction force also changes.

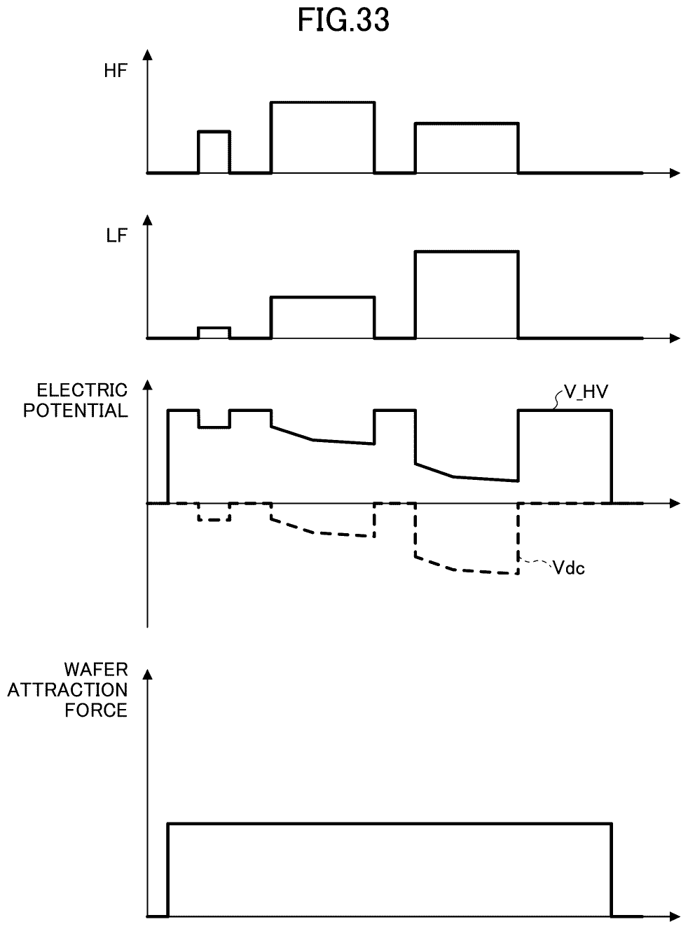

FIG. 33 is a graph indicating the wafer attraction force in an example of the plasma processing. Here, HF indicates the output of the source RF signal. LF indicates the output of the RF bias signal. As the electric potential, the voltage V_HV applied from the chuck power supply 15 and the self-bias voltage Vdc are indicated. The wafer attraction force indicates the electrostatic attraction force of the substrate W. The horizontal axis indicates the time. Here, the substrate W is subjected to plasma processing by using HF and LF illustrated in FIG. 33. At this time, the self-bias voltage Vdc illustrated by a dashed line is generated. In the plasma processing, the self-bias voltage Vdc changes in accordance with the plasma processing conditions (HF and LF).

Here, the controller 2 controls the voltage V_HV (indicated by the solid line) applied from the chuck power supply 15 to the electrostatic electrode 1111b so that (V_HV−Vdc) is constant. That is, the controller 2 changes the voltage V_HV (indicated by the solid line) applied from the chuck power supply 15 to the electrostatic electrode 1111b in accordance with the self-bias voltage Vdc (indicated by the dashed line). With this, the wafer attraction force can be constant.

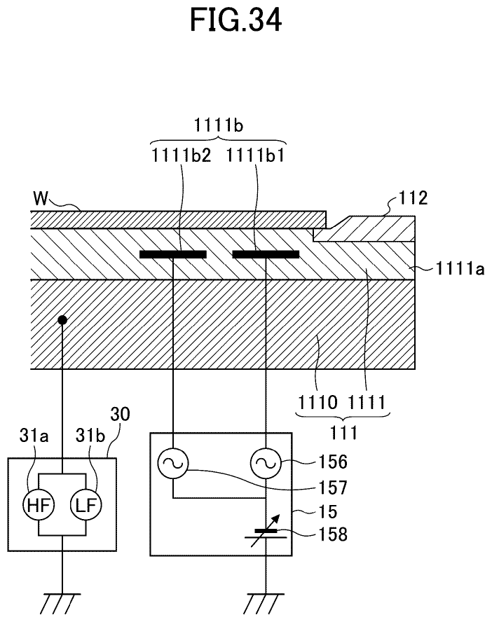

Next, a case where the AC voltage V_HV is applied from the chuck power supply 15 to the electrostatic electrode 1111b will be described with reference to FIGS. 34 to 37.

FIG. 34 is an example of a partially enlarged cross-sectional view of the substrate support 11 and a view indicating a relationship between the voltage and the electric potential.

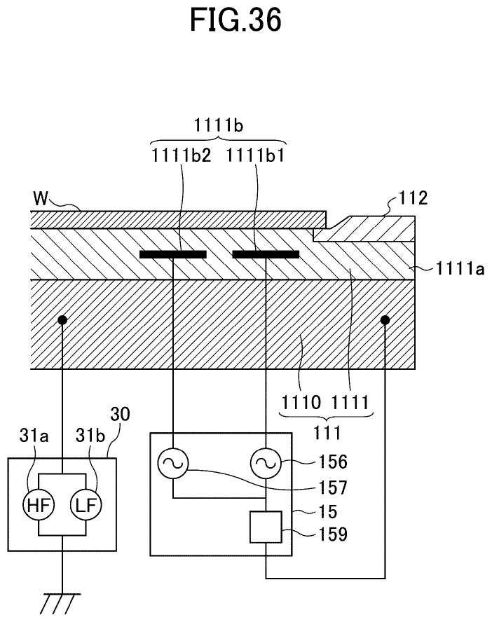

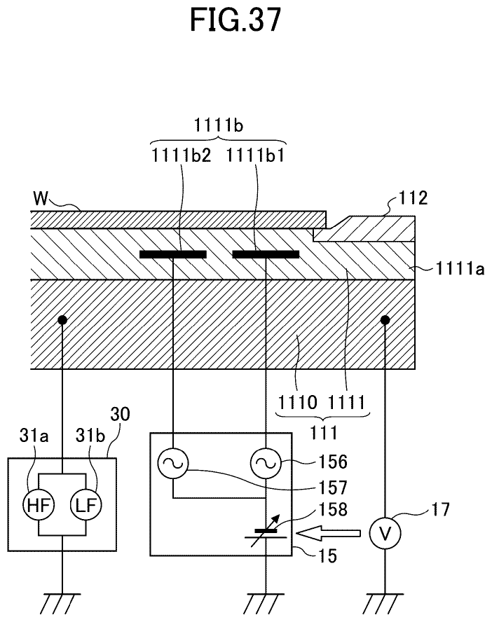

To the conductive member of the base 1110 that functions as the lower electrode, a source RF signal (hereinafter, which is also referred to as HF) is supplied from the first RF generator 31a and a RF bias signal (hereinafter, which is also referred to as LF) is supplied from the second RF generator 31b. Additionally, in the example of FIG. 34 (and FIGS. 36 and 37, which will be described later), a case where the electrostatic electrode 1111b is two-pole (the first chuck electrode 1111b1 and the second chuck electrode 1111b2) will be described as an example. The chuck power supply 15 includes a first AC power supply 156, a second AC power supply 157, and a DC power supply 158.

The first AC power supply 156 applies an AC voltage to the first chuck electrode 1111b1. The second AC power supply 157 applies an AC voltage to the second chuck electrode 1111b2. The DC power supply 158 is arranged in series with respect to the first AC power supply 156 and the second AC power supply 157.

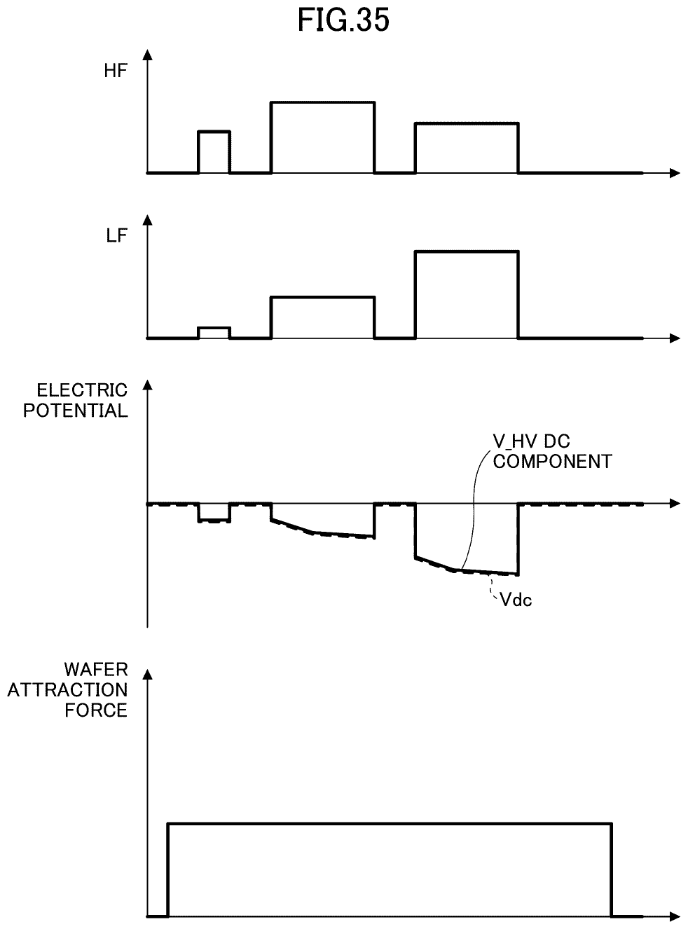

FIG. 35 is a graph indicating a wafer attraction force in an example of the plasma processing. Here, HF indicates the output of the source RF signal. LF indicates the output of the RF bias signal. As the electric potential, a direct current (DC) component (that is, the voltage component of the DC power supply 158) of the voltage V_HV applied from the chuck power supply 15 and the self-bias voltage Vdc are indicated. The wafer attraction force indicates the electrostatic attraction force of the substrate W. The horizontal axis indicates the time. Here, the substrate W is subjected to the plasma processing by using HF and LF illustrated in FIG. 35. At this time, the self-bias voltage Vdc indicated by the dashed line is generated. In the plasma processing, the self-bias voltage Vdc changes in accordance with the plasma processing conditions (HF and LF).

Here, the controller 2 controls the DC power supply 158 so that the DC component of the voltage V_HV applied from the chuck power supply 15 matches the self-bias voltage Vdc. That is, the controller 2 controls the DC power supply 158 in accordance with the self-bias voltage Vdc. With this, the chuck power supply 15 applies, to the first chuck electrode 1111b1 and the second chuck electrode 1111b2, the AC voltage that is offset with the self-bias voltage Vdc. With this, the wafer attraction force can be constant.

FIG. 36 is an example of a partially enlarged cross-sectional view of the substrate support 11 and a view illustrating a relationship with the electric potential.

Here, the chuck power supply 15 includes the first AC power supply 156, the second AC power supply 157, and an RF filter 159. The first AC power supply 156 and the second AC power supply 157 are electrically connected to the conductive member of the base 1110 via the RF filter 159. The RF filter 159 removes the high-frequency component (the source RF signal and the RF bias signal) and transmits the DC component. Here, the electric potential of the conductive member of the base 1110 is the self-bias voltage Vdc. With this, the chuck power supply 15 applies, to the first chuck electrode 1111b1 and the second chuck electrode 1111b2, the AC voltage that is offset with the self-bias voltage Vdc. With this, the wafer attraction force can be constant.

Additionally, a battery, an insulating transformer, or the like can be used as the power supply to the first AC power supply 156 and the second AC power supply 157, which are floating in electric potential.

FIG. 37 is an example of a partially enlarged cross-sectional view of the substrate support 11 and a view illustrating a relationship with the electric potential.

Here, a voltage sensor 17 is provided to detect the electric potential of the base 1110, that is, the self-bias voltage Vdc. The controller 2 controls the DC power supply 158 based on the self-bias voltage Vdc detected by the voltage sensor 17. With this, the chuck power supply 15 applies, to the first chuck electrode 1111b1 and the second chuck electrode 1111b2, the AC voltage that is offset with the self-bias voltage Vdc. With this, the wafer attraction force can be constant.

The above-disclosed embodiments include, for example, the following embodiments.

(Clause 1) A plasma processing apparatus including:
a plasma processing chamber;
an electrostatic chuck disposed in the plasma processing chamber, the electrostatic chuck including a dielectric member including a substrate support surface and a ring support surface, and first to Nth (N is an integer greater than or equal to 2) chuck electrodes disposed under the ring support surface in the dielectric member;
an AC voltage generator configured to respectively apply first to Nth AC voltages to the first to Nth chuck electrodes, the first to Nth AC voltages being phase-shifted relative to each other; and
a controller configured to perform an edge ring replacement sequence,
wherein the edge ring replacement sequence includes:
   (a) changing the first to Nth AC voltages from an on state to an off state;
   (b) removing a first edge ring arranged on the ring support surface;
   (c) mounting a second edge ring on the ring support surface; and
   (d) changing the first to Nth AC voltages from the off state to the on state.

(Clause 2) The plasma processing apparatus described in Clause 1,
wherein the first to Nth chuck electrodes include a first chuck electrode and a second chuck electrode,
wherein the AC voltage generator includes:
   an AC power supply configured to apply the first AC voltage to the first chuck electrode; and
   a phase adjuster electrically connected between the AC power supply and the second chuck electrode and configured to apply, to the second chuck electrode, the second AC voltage that is phase-shifted from the first AC voltage.

(Clause 3) The plasma processing apparatus described in Clause 1,
wherein the first to Nth chuck electrodes include a first chuck electrode and a second chuck electrode,
wherein the AC voltage generator includes:
   a first AC power supply configured to apply the first AC voltage to the first chuck electrode; and
   a second AC power supply configured to apply, to the second chuck electrode, the second AC voltage that is phase-shifted from the first AC voltage.

(Clause 4) The plasma processing apparatus described in any one of Clauses 1 to 3, wherein the first to Nth AC voltages have a phase difference of 1/N×360°.

(Clause 5) The plasma processing apparatus described in any one of Clauses 1 to 4, wherein the first to Nth chuck electrodes have a ring shape.

(Clause 6) The plasma processing apparatus as described in any one of Clauses 1 to 4, wherein the first to Nth chuck electrodes have a spiral shape or a nest structure.

(Clause 7) The plasma processing apparatus as described in any one of Clauses 1 to 6, wherein the first to Nth AC voltages have a frequency in a range of 0.01 Hz to 100 Hz.

(Clause 8) A plasma processing apparatus including:
a plasma processing chamber;
a plasma generator configured to generate a plasma in the plasma processing chamber;
an electrostatic chuck disposed in the plasma processing chamber, the electrostatic chuck including a dielectric member including a substrate support surface and a ring support surface, and first to Nth (N is an integer greater than or equal to two) chuck electrodes disposed under the substrate support surface in the dielectric member;
an AC voltage generator electrically connected to the first to Nth chuck electrodes; and
a controller configured to perform a substrate chuck sequence,
wherein the substrate chuck sequence includes:
   (a) mounting a substrate on the substrate support surface;
   (b) generating a first plasma in the plasma processing chamber;
   (c) respectively applying first to Nth AC voltages to the first to Nth chuck electrodes, the first to Nth AC voltages having a first voltage level and a first frequency and being phase-shifted relative to each other;
   (d) stopping the generation of the first plasma;
   (e) changing the first to Nth AC voltages to have a second frequency greater than the first frequency while maintaining the first voltage level; and
   (f) generating a second plasma in the plasma processing chamber.

(Clause 9) The plasma processing apparatus described in Clause 8,
wherein the plasma generator includes a source radio frequency (RF) power generator configured to generate source RF power for plasma generation, and
wherein the source RF power has a first power level in (b), a zero power level in (d), and a second power level greater than the first power level in (f).

(Clause 10) The plasma processing apparatus described in Clause 8,
wherein the first to Nth chuck electrodes include a first chuck electrode and a second chuck electrode,
wherein the AC voltage generator includes:
   an AC power supply configured to apply the first AC voltage to the first chuck electrode; and
   a phase adjuster electrically connected between the AC power supply and the second chuck electrode and configured to apply, to the second chuck electrode, the second AC voltage that is phase-shifted from the first AC voltage.

(Clause 11) The plasma processing apparatus as described in any one of Clauses 8 to 10, wherein the first to Nth AC voltages have a phase difference of 1/N×360°.

(Clause 12) The plasma processing apparatus as described in any one of Clauses 8 to 11, wherein the first to Nth chuck electrodes have a circular or ring shape.

(Clause 13) The plasma processing apparatus as described in any one of Clauses 8 to 11, wherein the first to Nth chuck electrodes have a spiral shape or a nest structure.

(Clause 14) The plasma processing apparatus as described in any one of Clauses 8 to 13, wherein the first to Nth AC voltages have a frequency in a range of 0.01 Hz to 100 Hz.

(Clause 15) The plasma processing apparatus as described in any one of Clauses 8 to 14,
wherein the controller is configured to perform a substrate dechuck sequence, and
wherein the substrate dechuck sequence includes:
   (g) changing the first to Nth AC voltages to have a third frequency greater than the second frequency while maintaining the first voltage level;
   (h) generating a third plasma in the plasma processing chamber;
   (i) starting decreasing the voltage level of the first to Nth AC voltages; and
   (j) stopping the generation of the third plasma.

(Clause 16) The plasma processing apparatus as described in Clause 15, wherein (j) is performed after the first to Nth AC voltages are reduced to a zero voltage level.

(Clause 17) The plasma processing apparatus as described in Clause 15, wherein (j) is performed before the first to Nth AC voltages are reduced to a zero voltage level.

(Clause 18) A substrate attraction method of a plasma processing apparatus including a plasma processing chamber; a plasma generator configured to generate a plasma in the plasma processing chamber; and an electrostatic chuck disposed in the plasma processing chamber, the electrostatic chuck including a dielectric member including a substrate support surface and a ring support surface; a plurality of chuck electrodes disposed under the substrate support surface in the dielectric member; an AC voltage generator configured to apply an AC voltage to the plurality of chuck electrodes; and a controller configured to perform a process of electrostatically attracting a substrate onto the substrate support surface, the substrate attraction method including:
mounting the substrate on the substrate support surface;
generating, by controlling the plasma generator, a first plasma in the plasma processing chamber;
applying, by controlling the AC voltage generator, the AC voltages having a first voltage level and a first frequency to the plurality of chuck electrodes;
stopping, by controlling the plasma generator, the generation of the first plasma;
changing, by controlling the AC voltage generator, the AC voltage to be applied to the plurality of chuck electrodes to have a second frequency greater than the first frequency while maintaining the first voltage level; and
generating, by controlling the plasma generator, a second plasma in the plasma processing chamber.

The above-disclosed embodiments include, for example, the following embodiments.

(Clause 1) A plasma processing apparatus including:
a plasma processing chamber;
an electrostatic chuck disposed in the plasma processing chamber, the electrostatic chuck including a dielectric member including a substrate support surface and a ring support surface, and a plurality of chuck electrodes disposed under the ring support surface in the dielectric member; and
an alternating current (AC) voltage generator configured to apply AC voltages to the plurality of chuck electrodes, the AC voltages being phase-shifted relative to each other,
wherein the plurality of chuck electrodes include one chuck electrode and another chuck electrode,
wherein the one chuck electrode includes a plurality of arc portions,
wherein the another chuck electrode includes a plurality of arc portions, and
wherein the arc portions of the one chuck electrode and the arc portions of the another chuck electrode are arranged alternately in a radial direction.

(Clause 2) The plasma processing apparatus as described in Clause 1,
wherein the one chuck electrode includes a first arc portion, a third arc portion, and a first connection that connects the first arc portion to the third arc portion,
wherein the another chuck electrode includes a second arc portion, a fourth arc portion, and a second connection that connects the second arc portion to the fourth arc portion, and
wherein the first arc portion, the second arc portion, the third arc portion, and the fourth arc portion are arranged in this order in a radial direction from an outer peripheral side to a center side.

(Clause 3) The plasma processing apparatus described in Clause 1 or Clause 2, wherein the plurality of chuck electrodes have a spiral shape or a nested structure.

(Clause 4) The plasma processing apparatus described in any one of Clauses 1 to 3, further including a controller configured to perform an edge ring replacement sequence,
wherein the plurality of chuck electrodes include first to Nth (N is an integer greater than or equal to 2) chuck electrodes disposed under the ring support surface in the dielectric member;
wherein the AC voltage generator is configured to respectively apply first to Nth AC voltages to the first to Nth chuck electrodes, the first to Nth AC voltages being phase-shifted relative to each other,
wherein the edge ring replacement sequence includes:
   (a) changing the first to Nth AC voltages from an on state to an off state;
   (b) removing a first edge ring arranged on the ring support surface;
   (c) mounting a second edge ring on the ring support surface;
   (d) changing the first to Nth AC voltages from the off state to the on state.

(Clause 5) The plasma processing apparatus described in Clause 4,
wherein the first to Nth chuck electrodes include a first chuck electrode and a second chuck electrode, and
wherein the AC voltage generator includes:
   a power supply configured to apply the first AC voltage to the first chuck electrode;
   a phase adjuster electrically connected between the power supply and the second chuck electrode and configured to apply, to the second chuck electrode, the second AC voltage that is phase-shifted from the first AC voltage.

(Clause 6) The plasma processing apparatus described in Clause 4,
wherein the first to Nth chuck electrodes include a first chuck electrode and a second chuck electrode, and
wherein the AC voltage generator includes:
   a first power supply configured to apply the first AC voltage to the first chuck electrode; and
   a second power supply configured to apply, to the second chuck electrode, the second AC voltage that is phase-shifted from the first AC voltage.

(Clause 7) The plasma processing apparatus described in any one of Clauses 4 to 6, wherein the first to Nth AC voltages have a phase difference of 1/N×360°.

(Clause 8) The plasma processing apparatus described in any one of Clauses 4 to 7, wherein the first to Nth AC voltages have a frequency in a range of 0.01 Hz to 100 Hz.

(Clause 9) The plasma processing apparatus described in any one of Clauses 4 to 8, wherein the first to Nth AC voltages are offset with a self-bias voltage.

(Clause 10) A plasma processing apparatus including:
a plasma processing chamber;
an electrostatic chuck disposed in the plasma processing chamber, the electrostatic chuck including a dielectric member including a substrate support surface and a ring support surface, and first to Nth (N is an integer greater than or equal to 2) chuck electrodes disposed under the ring support surface in the dielectric member;
an AC voltage generator configured to respectively apply first to Nth AC voltages to the first to Nth chuck electrodes, the first to Nth AC voltages being phase-shifted relative to each other; and
a controller configured to perform an edge ring replacement sequence,
wherein the edge ring replacement sequence includes:
   (a) changing the first to Nth AC voltages from an on state to an off state;
   (b) removing a first edge ring arranged on the ring support surface;
   (c) mounting a second edge ring on the ring support surface; and
   (d) changing the first to Nth AC voltages from the off state to the on state.

(Clause 11) The plasma processing apparatus described in Clause 9, wherein the first to Nth chuck electrodes have a ring shape.

(Clause 12) A plasma processing apparatus including:
a plasma processing chamber;
a plasma generator configured to generate a plasma in the plasma processing chamber;
an electrostatic chuck disposed in the plasma processing chamber, the electrostatic chuck including a dielectric member including a substrate support surface and a ring support surface, and first to Nth (N is an integer greater than or equal to two) chuck electrodes disposed under the substrate support surface in the dielectric member;
an AC voltage generator electrically connected to the first to Nth chuck electrodes; and
a controller configured to perform a substrate chuck sequence,
wherein the substrate chuck sequence includes:
   (a) mounting a substrate on the substrate support surface;
   (b) generating a first plasma in the plasma processing chamber;
   (c) respectively applying first to Nth AC voltages to the first to Nth chuck electrodes, the first to Nth AC voltages having a first voltage level and a first frequency and being phase-shifted relative to each other;
   (d) stopping the generation of the first plasma;
   (e) changing the first to Nth AC voltages to have a second frequency greater than the first frequency while maintaining the first voltage level; and
   (f) generating a second plasma in the plasma processing chamber.

(Clause 13) The plasma processing apparatus described in Clause 12,
wherein the plasma generator includes a source radio frequency (RF) power generator configured to generate source RF power for plasma generation, and
wherein the source RF power has a first power level in (b), a zero power level in (d), and a second power level greater than the first power level in (f).

(Clause 14) The plasma processing apparatus described in Clause 12,
wherein the first to Nth chuck electrodes include a first chuck electrode and a second chuck electrode,
wherein the AC voltage generator includes:
   a power supply configured to apply the first AC voltage to the first chuck electrode; and
   a phase adjuster electrically connected between the power supply and the second chuck electrode and configured to apply, to the second chuck electrode, the second AC voltage that is phase-shifted from the first AC voltage.

(Clause 15) The plasma processing apparatus as described in any one of Clauses 12 to 14, wherein the first to Nth AC voltages have a phase difference of 1/N×360°.

(Clause 16) The plasma processing apparatus as described in any one of Clauses 12 to 15, wherein the first to Nth chuck electrodes have a circular or ring shape.

(Clause 17) The plasma processing apparatus as described in any one of Clauses 12 to 16, wherein the first to Nth chuck electrodes have a spiral shape or a nest structure.

(Clause 18) The plasma processing apparatus as described in any one of Clauses 12 to 18, wherein the first to Nth AC voltages have a frequency in a range of 0.01 Hz to 100 Hz.

(Clause 19) The plasma processing apparatus as described in any one of Clauses 12 to 15,
wherein the controller is configured to perform a substrate dechuck sequence, and
wherein the substrate dechuck sequence includes:
   (g) changing the first to Nth AC voltages to have a third frequency greater than the second frequency while maintaining the first voltage level;
   (h) generating a third plasma in the plasma processing chamber;
   (i) starting decreasing the voltage level of the first to Nth AC voltages; and
   (j) stopping the generation of the third plasma.

(Clause 20) The plasma processing apparatus as described in Clause 19, wherein (j) is performed after the first to Nth AC voltages are reduced to a zero voltage level.

(Clause 21) The plasma processing apparatus as described in Clause 19, wherein (j) is performed before the first to Nth AC voltages are reduced to a zero voltage level.

(Clause 22) A substrate attraction method of a plasma processing apparatus including a plasma processing chamber; a plasma generator configured to generate a plasma in the plasma processing chamber; and an electrostatic chuck disposed in the plasma processing chamber, the electrostatic chuck including a dielectric member including a substrate support surface and a ring support surface; a plurality of chuck electrodes disposed under the substrate support surface in the dielectric member; an AC voltage generator configured to apply an AC voltage to the plurality of chuck electrodes; and a controller configured to perform a process of electrostatically attracting a substrate onto the substrate support surface, the substrate attraction method including:
mounting the substrate on the substrate support surface;
generating, by controlling the plasma generator, a first plasma in the plasma processing chamber;
applying, by controlling the AC voltage generator, the AC voltages having a first voltage level and a first frequency to the plurality of chuck electrodes;
stopping, by controlling the plasma generator, the generation of the first plasma;
changing, by controlling the AC voltage generator, the AC voltage to be applied to the plurality of chuck electrodes to have a second frequency greater than the first frequency while maintaining the first voltage level; and
generating, by controlling the plasma generator, a second plasma in the plasma processing chamber.

It should be noted that the present invention is not limited to the configuration illustrated here, such as the configurations listed in the above embodiments and a combination with other elements. These points can be changed without departing from the scope and spirit of the present invention, and can be appropriately determined according to the application form thereof.

What is claimed is:

1. A plasma processing apparatus comprising:
a plasma processing chamber;
an electrostatic chuck disposed in the plasma processing chamber, the electrostatic chuck including a dielectric member including a substrate support surface and a ring support surface, a plurality of chuck electrodes disposed under the substrate support surface in the dielectric member, and a plurality of chuck electrodes disposed under the ring support surface in the dielectric member; and
an alternating current (AC) voltage generator configured to apply AC voltages to the plurality of chuck electrodes disposed under the ring support surface, the AC voltages being phase-shifted relative to each other,
wherein the plurality of chuck electrodes disposed under the ring support surface include one chuck electrode and another chuck electrode,
wherein the one chuck electrode includes a plurality of arc portions,
wherein the another chuck electrode includes a plurality of arc portions,
wherein the arc portions of the one chuck electrode and the arc portions of the another chuck electrode are arranged alternately in a radial direction, and
wherein the plurality of chuck electrodes disposed under the substrate support surface have a spiral shape and the plurality of chuck electrodes disposed under the ring support surface have a nested structure.

2. The plasma processing apparatus as claimed in claim 1,
wherein the one chuck electrode includes a first arc portion, a third arc portion, and a first connection that connects the first arc portion to the third arc portion,
wherein the another chuck electrode includes a second arc portion, a fourth arc portion, and a second connection that connects the second arc portion to the fourth arc portion, and
wherein the first arc portion, the second arc portion, the third arc portion, and the fourth arc portion are arranged in this order in a radial direction from an outer peripheral side to a center side.

3. The plasma processing apparatus as claimed in claim 1, further comprising a controller configured to perform an edge ring replacement sequence,
wherein the plurality of chuck electrodes disposed under the ring support surface include first to Nth (N is an integer greater than or equal to 2) chuck electrodes disposed under the ring support surface in the dielectric member,
wherein the AC voltage generator is configured to respectively apply first to Nth AC voltages to the first to Nth chuck electrodes, the first to Nth AC voltages being phase-shifted relative to each other, and
wherein the edge ring replacement sequence includes:
(a) changing the first to Nth AC voltages from an on state to an off state;
(b) removing a first edge ring arranged on the ring support surface;
(c) mounting a second edge ring on the ring support surface; and
(d) changing the first to Nth AC voltages from the off state to the on state.

4. The plasma processing apparatus as claimed in claim 3,
wherein the first to Nth chuck electrodes include a first chuck electrode and a second chuck electrode, and
wherein the AC voltage generator includes:
a power supply configured to apply the first AC voltage to the first chuck electrode; and
a phase adjuster electrically connected between the power supply and the second chuck electrode and configured to apply, to the second chuck electrode, the second AC voltage that is phase-shifted from the first AC voltage.

5. The plasma processing apparatus as claimed in claim 3,
wherein the first to Nth chuck electrodes include a first chuck electrode and a second chuck electrode, and
wherein the AC voltage generator includes:
a first power supply configured to apply the first AC voltage to the first chuck electrode; and
a second power supply configured to apply, to the second chuck electrode, the second AC voltage that is phase-shifted from the first AC voltage.

6. The plasma processing apparatus as claimed in claim 3, wherein the first to Nth AC voltages have a phase difference of 1/N×360°.

7. The plasma processing apparatus as claimed in claim 3, wherein the first to Nth AC voltages have a frequency in a range of 0.01 Hz to 100 Hz.

8. The plasma processing apparatus as claimed in claim 3, wherein the first to Nth AC voltages are offset with a self-bias voltage.

9. A plasma processing apparatus comprising:
a plasma processing chamber;
an electrostatic chuck disposed in the plasma processing chamber, the electrostatic chuck including a dielectric member including a substrate support surface and a ring support surface, and first to Nth (N is an integer greater than or equal to 2) chuck electrodes disposed under the ring support surface in the dielectric member;
an AC voltage generator configured to respectively apply first to Nth AC voltages to the first to Nth chuck electrodes, the first to Nth AC voltages being phase-shifted relative to each other; and
a controller configured to perform an edge ring replacement sequence,
wherein the edge ring replacement sequence includes:
(a) changing the first to Nth AC voltages from an on state to an off state;
(b) removing a first edge ring arranged on the ring support surface;
(c) mounting a second edge ring on the ring support surface; and
(d) changing the first to Nth AC voltages from the off state to the on state.

10. The plasma processing apparatus as claimed in claim 8, wherein the first to Nth chuck electrodes have a ring shape.

11. A plasma processing apparatus comprising:
a plasma processing chamber;
a plasma generator configured to generate a plasma in the plasma processing chamber;
an electrostatic chuck disposed in the plasma processing chamber, the electrostatic chuck including a dielectric member including a substrate support surface and a ring support surface, and first to Nth (N is an integer greater than or equal to two) chuck electrodes disposed under the substrate support surface in the dielectric member;
an AC voltage generator electrically connected to the first to Nth chuck electrodes; and
a controller configured to perform a substrate chuck sequence,
wherein the substrate chuck sequence includes:
(a) mounting a substrate on the substrate support surface;
(b) generating a first plasma in the plasma processing chamber;
(c) respectively applying first to Nth AC voltages to the first to Nth chuck electrodes, the first to Nth AC voltages having a first voltage level and a first frequency and being phase-shifted relative to each other;
(d) stopping the generation of the first plasma;
(e) changing the first to Nth AC voltages to have a second frequency greater than the first frequency while maintaining the first voltage level; and
(f) generating a second plasma in the plasma processing chamber.

12. The plasma processing apparatus as claimed in claim 11,
wherein the plasma generator includes a source radio frequency (RF) power generator configured to generate source RF power for plasma generation, and
wherein the source RF power has a first power level in (b), a zero power level in (d), and a second power level greater than the first power level in (f).

13. The plasma processing apparatus as claimed in claim 11,
wherein the first to Nth chuck electrodes include a first chuck electrode and a second chuck electrode,
wherein the AC voltage generator includes:
a power supply configured to apply the first AC voltage to the first chuck electrode; and
a phase adjuster electrically connected between the power supply and the second chuck electrode and configured to apply, to the second chuck electrode, the second AC voltage that is phase-shifted from the first AC voltage.

14. The plasma processing apparatus as claimed in claim 11, wherein the first to Nth AC voltages have a phase difference of 1/N×360°.

15. The plasma processing apparatus as claimed in claim 11, wherein the first to Nth chuck electrodes have a circular or ring shape.

16. The plasma processing apparatus as claimed in claim 11, wherein the first to Nth chuck electrodes have a spiral shape or a nest structure.

17. The plasma processing apparatus as claimed in claim 11, wherein the first to Nth AC voltages have a frequency in a range of 0.01 Hz to 100 Hz.

18. The plasma processing apparatus as claimed in claim 11,
wherein the controller is configured to perform a substrate dechuck sequence, and
wherein the substrate dechuck sequence includes:
(g) changing the first to Nth AC voltages to have a third frequency greater than the second frequency while maintaining the first voltage level;
(h) generating a third plasma in the plasma processing chamber;
(i) starting decreasing the voltage level of the first to Nth AC voltages; and
(j) stopping the generation of the third plasma.

19. The plasma processing apparatus as claimed in claim 18, wherein (j) is performed after the first to Nth AC voltages are reduced to a zero voltage level.

20. The plasma processing apparatus as claimed in claim 18, wherein (j) is performed before the first to Nth AC voltages are reduced to a zero voltage level.
